(19) United States
(12) Patent Application Publication
(10) Pub. No.: US 2025/0210598 A1
(43) Pub. Date: Jun. 26, 2025

(54) DISPLAY DEVICE

(71) Applicant: Samsung Display Co., LTD., Yongin-si (KR)

(72) Inventors: Ki Nyeng KANG, Yongin-si (KR); Sung Hoon KIM, Yongin-si (KR); Ock Soo SON, Yongin-si (KR); Keun Kyu SONG, Yongin-si (KR)

(73) Assignee: Samsung Display Co., LTD., Yongin-si (KR)

(21) Appl. No.: 18/772,930

(22) Filed: Jul. 15, 2024

(30) Foreign Application Priority Data
Dec. 22, 2023 (KR) 10-2023-0190023

(51) Int. Cl. H01L 25/075

(52) U.S. Cl. CPC H01L 25/0753

(57) ABSTRACT

A display device includes a substrate, and a bank layer disposed on the substrate, and defining a first emission area, a second emission area, and a third emission area. Each of the first emission area, the second emission area, and the third emission area includes a first electrode and a second electrode extending in a first direction and spaced apart from each other in a second direction intersecting the first direction, and a plurality of light emitting elements disposed between the first electrode and the second electrode, the first emission area and the second emission area are adjacent to each other in the first direction, the third emission area is spaced apart from the first emission area or the second emission area in the second direction, and the first emission area, the second emission area, and the third emission area emit light of different colors.

### CROSS-REFERENCE TO RELATED APPLICATION(S)

This application claims priority to and benefits of Korean Patent Application No. 10-2023-0190023 under 35 U.S.C. 119, filed on Dec. 22, 2023, in the Korean Intellectual Property Office (KIPO), the entire contents of which are incorporated herein by reference.

### BACKGROUND

### 1. Technical Field

The disclosure relates to a display device.

### 2. Description of the Related Art

The importance of display devices has steadily increased with the development of multimedia technology. Along with this trend, various types of display devices such as an organic light emitting display (OLED), a liquid crystal display (LCD) and the like have been used.

As a device for displaying an image of a display device, there is a self-light emitting display device including a light emitting element. The self-light emitting display device includes an organic light emitting display device using an organic material as a light emitting material as a light emitting element, an inorganic light emitting display device using an inorganic material as a light emitting material, or the like.

### SUMMARY

Aspects of the disclosure provide a high-resolution display device by reducing the number of electrodes that align light emitting elements.

However, aspects of the disclosure are not restricted to the one set forth herein. The above and other aspects of the disclosure will become more apparent to one of ordinary skill in the art to which the disclosure pertains by referencing the detailed description of the disclosure given below.

According to an embodiment of the disclosure, a display device may include a substrate, and a bank layer disposed on the substrate, and defining a first emission area, a second emission area, and a third emission area. Each of the first emission area, the second emission area, and the third emission area may include a first electrode and a second electrode extending in a first direction and spaced apart from each other in a second direction intersecting the first direction, and a plurality of light emitting elements disposed between the first electrode and the second electrode. The first emission area and the second emission area may be adjacent to each other in the first direction, the third emission area may be spaced apart from the first emission area or the second emission area in the second direction, and the first emission area, the second emission area, and the third emission area may emit light of different colors.

In an embodiment, an extension direction of the first electrode of the first emission area may be aligned with an extension direction of the first electrode of the second emission area, and an extension direction of the second electrode of the first emission area may be aligned with an extension direction of the second electrode of the second emission area.

In an embodiment, the first electrode of the third emission area may be spaced apart from the first electrode of the first emission area in the second direction, and the second electrode of the third emission area may be spaced apart from the second electrode of the first emission area in the second direction.

In an embodiment, the first emission area may emit red light, the second emission area may emit blue light, and the third emission area may emit green light.

In an embodiment, a size of the third emission area may be greater than a size of the first emission area or a size the second emission area in a plan view.

In an embodiment, the size of the first emission area may be equal to the size of the second emission area.

In an embodiment, each of the first emission area, the second emission area, and the third emission area may further include a third electrode disposed between the first electrode and the second electrode, and the plurality of light emitting elements may include first light emitting elements disposed between the first electrode and the third electrode and second light emitting elements disposed between the second electrode and the third electrode.

In an embodiment, the display device may further include a fourth emission area and a fifth emission area spaced apart in the second direction with the third emission area interposed between the fourth emission area and the fifth emission area. Each of the fourth emission area and the fifth emission area may include the first electrode, the second electrode, and the plurality of light emitting elements.

In an embodiment, the fourth emission area and the first emission area may emit light of a same color, and the fifth emission area and the second emission area may emit light of a same color.

In an embodiment, each of the second electrode of the first emission area and the second electrode of the second emission area may be connected to the first electrode of the third emission area, and the first electrode of the fourth emission area and the first electrode of the fifth emission area may be connected to the second electrode of the third emission area.

According to an embodiment of the disclosure, a display device may include a substrate, and a bank layer disposed on the substrate, and defining a first emission area, a second emission area, a third emission area, and a fourth emission area. Each of the first emission area, the second emission area, the third emission area, and the fourth emission area may include a first electrode and a second electrode extending in a first direction and spaced apart from each other in a second direction intersecting the first direction, and a plurality of light emitting elements disposed between the first electrode and the second electrode. The first emission area and the second emission area may be adjacent to each other in the first direction, the third emission area and the fourth emission area may be adjacent to each other in the first direction, the third emission area and the fourth emission area may be spaced apart from the first emission area or the second emission area in the second direction, the first emission area, the second emission area, and the third emission area may emit light of different colors, and the third emission area and the fourth emission area may emit light of a same color.

In an embodiment, an extension direction of the first electrode of the first emission area may be aligned with an extension direction of the first electrode of the second emission area, and an extension direction of the first electrode of the third emission area may be aligned with an extension direction of the first electrode of the fourth emission area.

In an embodiment, the first electrode of the third emission area and the first electrode of the fourth emission area may be spaced apart from the first electrode of the first emission area in the second direction, and the second electrode of the third emission area and the second electrode of the fourth emission area may be spaced apart from the second electrode of the first emission area in the second direction.

In an embodiment, the first emission area may emit red light, the second emission area may emit blue light, and the third emission area and the fourth emission area may emit green light.

In an embodiment, sizes the first emission area, the second emission area, the third emission area, and the fourth emission area may be equal in a plan view.

In an embodiment, lengths the first electrode of the first emission area, the first electrode of the second emission area, the first electrode of the third emission area, and the first electrode of the fourth emission area may be equal in the first direction.

In an embodiment, each of the first emission area, the second emission area, the third emission area, and the fourth emission area may further include a third electrode disposed between the first electrode and the second electrode, and the plurality of light emitting elements may include first light emitting elements disposed between the first electrode and the third electrode and second light emitting elements disposed between the second electrode and the third electrode.

In an embodiment, the display device may further include a fifth emission area and a sixth emission area spaced apart in the second direction with the third emission area interposed between the fifth emission area and the sixth emission area. Each of the fifth emission area and the sixth emission area may include the first electrode, the second electrode, and the plurality of light emitting elements.

In an embodiment, the fifth emission area and the second emission area may emit light of a same color, and the sixth emission area and the first emission area may emit light of a same color.

In an embodiment, each of the second electrode of the first emission area and the second electrode of the second emission area may be connected to the first electrode of the third emission area, and the first electrode of the fifth emission area and the first electrode of the sixth emission area may be connected to the second electrode of the third emission area.

In the display device according to one embodiment, since emission areas adjacent to each other in a first or second direction are disposed to emit light of different colors, the number of electrodes may be reduced and thus more emission areas may be formed, thereby implementing a high-resolution display device.

However, effects according to the embodiments of the disclosure are not limited to those exemplified above and various other effects are incorporated herein.

### BRIEF DESCRIPTION OF THE DRAWINGS

The above and other aspects and features of the disclosure will become more apparent by describing in detail embodiments thereof with reference to the attached drawings, in which:

FIG. 1 is a schematic plan view of a display device according to one embodiment;

FIG. 2 is a plan view illustrating a disposition of multiple wires included in a display device according to one embodiment;

FIG. 3 is a schematic diagram of an equivalent circuit of a sub-pixel according to one embodiment;

FIG. 4 is a plan view illustrating one sub-pixel of a display device according to one embodiment;

FIG. 5 is a schematic cross-sectional view taken along line E1-E1′ of FIG. 4;

FIG. 6 is a schematic cross-sectional view taken along line E2-E2′ of FIG. 4;

FIG. 7 is a schematic perspective view of a light emitting element according to one embodiment;

FIG. 8 is a schematic cross-sectional view of a display device according to one embodiment;

FIG. 9 is a plan view illustrating multiple pixels of a display device according to one embodiment;

FIG. 10 is a plan view illustrating multiple pixels of a display device according to another embodiment;

FIG. 11 is a plan view illustrating multiple pixels of a display device according to still another embodiment;

FIG. 12 is a plan view illustrating multiple pixels of a display device according to still another embodiment;

FIG. 13 is a plan view illustrating multiple pixels of a display device according to still another embodiment;

FIG. 14 is a plan view illustrating multiple pixels of a display device according to still another embodiment;

FIG. 15 is a plan view illustrating multiple pixels of a display device according to still another embodiment;

FIG. 16 is a plan view illustrating multiple pixels of a display device according to still another embodiment;

FIG. 17 is a plan view illustrating multiple pixels of a display device according to still another embodiment; and

FIG. 18 is a plan view illustrating multiple pixels of a display device according to still another embodiment.

### DETAILED DESCRIPTION OF THE EMBODIMENTS

The disclosure will now be described more fully hereinafter with reference to the accompanying drawings, in which embodiments of the disclosure are shown. This disclosure may, however, be embodied in different forms and should not be construed as limited to the embodiments set forth herein. Rather, these embodiments are provided so that this disclosure will be more thorough and complete, and will more fully convey the scope of the disclosure to those skilled in the art.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element.“ ” The same reference numbers indicate the same components throughout the specification.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the disclosure. Similarly, the second element could also be termed the first element.

In the specification and the claims, the phrase “at least one of” is intended to include the meaning of “at least one selected from the group of” for the purpose of its meaning and interpretation. For example, “at least one of A and B” may be understood to mean “A, B, or A and B.” In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

Each of the features of the various embodiments of the disclosure may be combined or combined with each other, in part or in whole, and technically various interlocking and driving are possible. Each embodiment may be implemented independently of each other or may be implemented together in an association.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

Hereinafter, embodiments will be described with reference to the accompanying drawings.

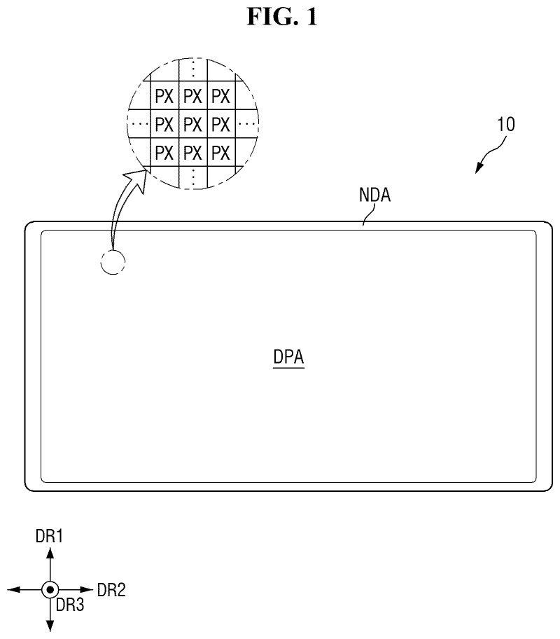

FIG. 1 is a schematic plan view of a display device according to one embodiment.

Referring to FIG. 1, a display device 10 may display a moving image or a still image. The display device 10 may be any electronic device providing a display screen. Examples of the display device 10 may include a television, a laptop computer, a monitor, a billboard, an Internet-of-Things device, a mobile phone, a smartphone, a tablet personal computer (PC), an electronic watch, a smart watch, a watch phone, a head-mounted display, a mobile communication terminal, an electronic notebook, an electronic book, a portable multimedia player (PMP), a navigation device, a game machine, a digital camera, a camcorder and the like, which provide a display screen.

The display device 10 may include a display panel which provides a display screen. Examples of the display panel may include an inorganic light emitting diode display panel, an organic light emitting display panel, a quantum dot light emitting display panel, a plasma display panel and a field emission display panel. In the following description, an embodiment that an inorganic light emitting diode display panel is applied as a display panel will be described, but the disclosure is not limited thereto, and other display panels may be applied within the same scope of technical spirit.

The shape of the display device 10 may be variously modified. For example, the display device 10 may have a shape such as a rectangular shape elongated in a horizontal direction, a rectangular shape elongated in a vertical direction, a square shape, a quadrilateral shape with rounded corners (vertices), another polygonal shape and a circular shape in a plan view. The shape of a display area DPA of the display device 10 may be similar to the overall shape of the display device 10. FIG. 1 schematically illustrates the display device 10 having a rectangular shape elongated in a second direction DR2.

The display device 10 may include the display area DPA and a non-display area NDA. The display area DPA may be an area where an image can be displayed, and the non-display area NDA may be an area where an image is not displayed. The display area DPA may be referred to as an active region, and the non-display area NDA may be referred to as a non-active region. The display area DPA may substantially occupy the center of the display device 10.

The display area DPA may include multiple pixels PX. The pixels PX may be arranged in a matrix. The shape of each pixel PX may be a rectangular or square shape in a plan view. However, the disclosure is not limited thereto, and the shape of each pixel PX may be a rhombic shape in which each side is inclined with respect to a direction. The pixels PX may be arranged in a stripe pattern or an island pattern. Each of the pixels PX may include one or more light emitting elements that emit light of a wavelength band to display a color.

The non-display area NDA may be disposed adjacent to the display area DPA. The non-display area NDA may completely or partially surround the display area DPA in a plan view. The display area DPA may have a rectangular shape in a plan view, and the non-display area NDA may be disposed adjacent to sides of the display area DPA. The non-display area NDA may form a bezel of the display device 10. Wires or circuit drivers included in the display device 10 may be disposed in the non-display area NDA, or external devices may be mounted on the non-display area NDA.

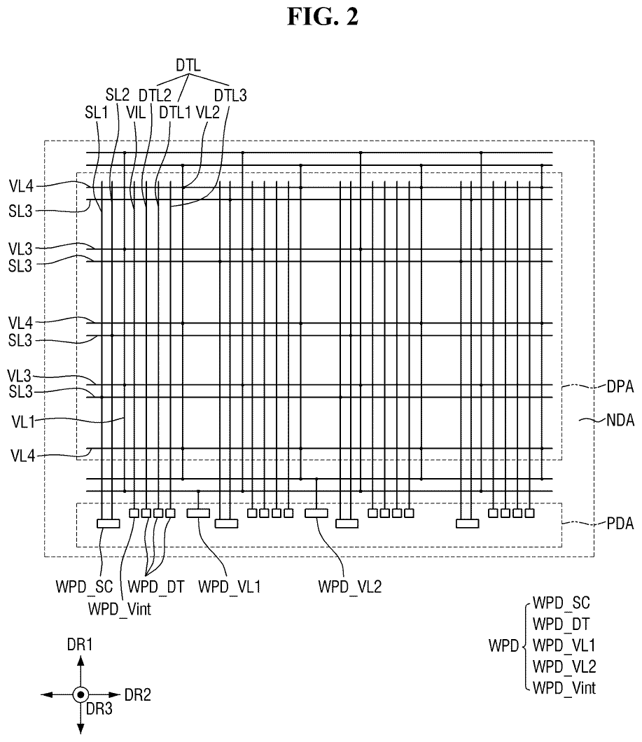

FIG. 2 is a plan view illustrating a disposition of multiple wires included in a display device according to one embodiment.

Referring to FIG. 2, the display device 10 may include multiple wires. The display device 10 may include multiple scan lines SL (SL1, SL2, and SL3), multiple data lines DTL (DTL1, DTL2, and DTL3), an initialization voltage line VIL, and multiple voltage lines VL (VL1, VL2, VL3, and VL4). Although not shown in the drawing, other wires may be further provided in the display device 10.

The first scan line SL1 and the second scan line SL2 may extend in a first direction DR1. The first scan line SL1 and the second scan line SL2 may be disposed adjacent to each other, and may be spaced apart from another first scan line SL1 and second scan line SL2 in the second direction DR2. The first scan line SL1 and the second scan line SL2 may be connected to a scan line pad WPD_SC connected to a scan driver (not illustrated). The first scan line SL1 and the second scan line SL2 may extend from a pad area PDA disposed in the non-display area NDA to the display area DPA.

The third scan line SL3 may extend in the second direction DR2, and may be spaced apart from another third scan line SL3 in the first direction DR1. A third scan line SL3 may be connected to one or more first scan lines SL1 or one or more second scan lines SL2. In one embodiment, the first scan line SL1 and the second scan line SL2 may be formed as a conductive layer disposed on a layer different from the third scan line SL3. The scan lines SL may have a mesh structure in the entire surface of the display area DPA, but the disclosure is not limited thereto.

The term “connected” as used herein may mean not only that a member is connected to another member through a physical contact, but also that a member is connected to another member through yet another member. This may also be understood as a part and another part as integral elements are connected into an integrated element via another element. Furthermore, if an element is connected to another element, this may be construed as a meaning including an electrical connection via another element in addition to a direct connection by physical contact.

The data lines DTL may extend in the first direction DR1. The data line DTL may include a first data line DTL1, a second data line DTL2, and a third data line DTL3, and the first to third data lines DTL1, DTL2, and DTL3 may form a pair and may be disposed adjacent to each other. Each of the data lines DTL1, DTL2, and DTL3 may extend from the pad area PDA disposed in the non-display area NDA to the display area DPA. However, the disclosure is not limited thereto, and the data lines DTL may be spaced apart from each other at equal intervals between a first voltage line VL1 and a second voltage line VL2 to be described below.

The initialization voltage line VIL may extend in the first direction DR1. The initialization voltage line VIL may be disposed between the data lines DTL and the first scan line SL1 and the second scan line SL2. The initialization voltage line VIL may extend from the pad area PDA disposed in the non-display area NDA to the display area DPA.

The first voltage line VL1 and the second voltage line VL2 may extend in the first direction DR1, and a third voltage line VL3 and a fourth voltage line VL4 may extend in the second direction DR2. The first voltage line VL1 and the second voltage line VL2 may be alternately disposed in the second direction DR2, and the third voltage line VL3 and the fourth voltage line VL4 may be alternately disposed in the first direction DR1. The first voltage line VL1 and the second voltage line VL2 may extend in the first direction DR1 across the display area DPA, some of the third voltage line VL3 and the fourth voltage line VL4 may be disposed in the display area DPA, and others of the third voltage line VL3 and the fourth voltage line VL4 may be disposed in the non-display area NDA located on sides of the display area DPA in the first direction DR1. The first voltage line VL1 and the second voltage line VL2 may be formed as a conductive layer disposed on a layer different from the third voltage line VL3 and the fourth voltage line VL4. The first voltage line VL1 may be connected to at least one third voltage line VL3, the second voltage line VL2 may be connected to at least one fourth voltage line VL4, and the voltage lines VL may have a mesh structure in the entire display area DPA. However, the disclosure is not limited thereto.

The first scan line SL1, the second scan line SL2, the data line DTL, the initialization voltage line VIL, the first voltage line VL1, and the second voltage line VL2 may be electrically connected to at least one line pad WPD. Each line pad WPD may be disposed in the non-display area NDA. In one embodiment, each of the line pads WPD may be disposed in the pad area PDA located on the lower side, which is another side of the display area DPA in the first direction DR1. The first scan line SL1 and the second scan line SL2 may be connected to the scan line pad WPD_SC disposed in the pad area PDA, and the data lines DTL may be connected to corresponding data line pads WPD_DT, respectively. The initialization voltage line VIL may be connected to an initialization line pad WPD_Vint, the first voltage line VL1 may be connected to a first voltage line pad WPD_VL1, and the second voltage line VL2 may be connected to a second voltage line pad WPD_VL2. The external devices may be mounted on the line pads WPD. The external devices may be mounted on the line pads WPD by applying an anisotropic conductive film, ultrasonic bonding or the like. The drawing illustrates that each of the line pads WPD is disposed in the pad area PDA disposed on the lower side of the display area DPA, but the disclosure is not limited thereto. Some of the line pads WPD may be disposed in an area on the upper side or on the left and right sides of the display area DPA.

Each pixel PX or sub-pixel SPXn (n is an integer of 1 to 3) of the display device 10 may include a pixel driving circuit. The above-described wires may pass through each pixel PX or the vicinity of each pixel PX to apply a driving signal to each pixel driving circuit. The pixel driving circuit may include transistors and capacitors. The number of the transistors and the capacitors of each pixel driving circuit may be variously modified. According to one embodiment, in each sub-pixel SPXn of the display device 10, the pixel driving circuit may have a 3T1C structure including three transistors and one capacitor. Hereinafter, the pixel driving circuit of the 3T1C structure will be described according to an embodiment, but the disclosure is not limited thereto, and various other modified structures such as a 2T1C structure, a 7T1C structure, and a 6T1C structure may be applied.

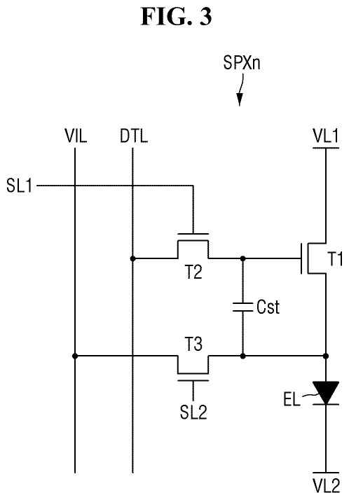

FIG. 3 is a schematic diagram of an equivalent circuit of a sub-pixel according to one embodiment.

Referring to FIG. 3, each sub-pixel SPXn of the display device 10 according to one embodiment may include three transistors T1, T2 and T3 and one storage capacitor Cst in addition to a light emitting diode EL.

The light emitting diode EL may emit light by a current supplied through a first transistor T1. The light emitting diode EL may include a first electrode, a second electrode, and at least one light emitting element disposed between the first electrode and the second electrode. The light emitting element may emit light of a wavelength band by electrical signals transmitted from the first electrode and the second electrode.

An end of the light emitting diode EL may be connected to the source electrode of the first transistor T1, and another end of the light emitting diode EL may be connected to the second voltage line VL2 to which a low potential voltage (hereinafter, a second power voltage) lower than a high potential voltage (hereinafter, a first power voltage) of the first voltage line VL1 is supplied.

The first transistor T1 may adjust a current flowing from the first voltage line VL1, to which the first power voltage is supplied, to the light emitting diode EL according to the voltage difference between the gate electrode and the source electrode. For example, the first transistor T1 may be a driving transistor for driving the light emitting diode EL. The gate electrode of the first transistor T1 may be connected to the source electrode of a second transistor T2, the source electrode of the first transistor T1 may be connected to the first electrode of the light emitting diode EL, and the drain electrode of the first transistor T1 may be connected to the first voltage line VL1 to which the first power voltage is applied.

The second transistor T2 may be turned on by a scan signal of the first scan line SL1 to connect the data line DTL to the gate electrode of the first transistor T1. The gate electrode of the second transistor T2 may be connected to the first scan line SL1, the source electrode of the second transistor T2 may be connected to the gate electrode of the first transistor T1, and the drain electrode of the second transistor T2 may be connected to the data line DTL.

A third transistor T3 may be turned on by a scan signal of the second scan line SL2 to connect the initialization voltage line VIL to an end of the light emitting diode EL. The gate electrode of the third transistor T3 may be connected to the second scan line SL2, the drain electrode of the third transistor T3 may be connected to the initialization voltage line VIL, and the source electrode of the third transistor T3 may be connected to an end of the light emitting diode EL or to the source electrode of the first transistor T1.

However, the source electrode and the drain electrode of each of the transistors T1, T2, and T3 are not limited to those described above. Each of the transistors T1, T2, and T3 may be formed of a thin film transistor. In FIG. 3, each of the transistors T1, T2, and T3 is described as being formed of an N-type metal oxide semiconductor field effect transistor (MOSFET), but the disclosure is not limited thereto. In another embodiment, each of the transistors T1, T2, and T3 may be formed of a P-type MOSFET. In another embodiment, some of the transistors T1, T2, and T3 may be formed of an N-type MOSFET, and others of the transistors T1, T2, and T3 may be formed of a P-type MOSFET.

The storage capacitor Cst may be formed between the gate electrode and the source electrode of the first transistor T1. The storage capacitor Cst may store a voltage difference between a gate voltage and a source voltage of the first transistor T1.

Hereinafter, a structure of a pixel PX of the display device 10 according to one embodiment will be described in detail with further reference to other drawings.

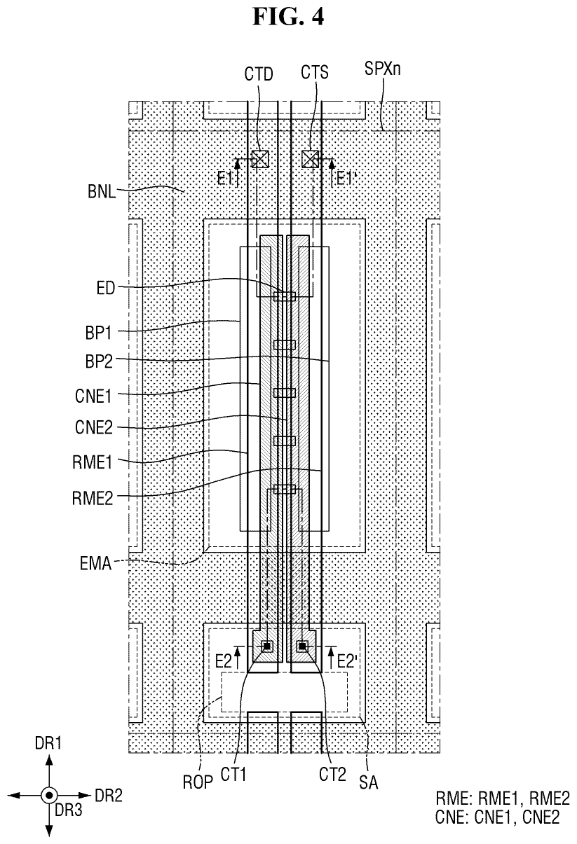

FIG. 4 is a plan view illustrating one sub-pixel of a display device according to one embodiment. FIG. 4 schematically illustrates a planar disposition of electrodes RME (RME1 and RME2), bank patterns BP1 and BP2, a bank layer BNL, multiple light emitting elements ED, and connection electrodes CNE (CNE1 and CNE2) disposed in one sub-pixel SPX of the display device 10.

Referring to FIG. 4, the display device 10 may include multiple sub-pixels SPXn. The sub-pixels SPXn may constitute one pixel. Each sub-pixel SPXn of the display device 10 may include an emission area EMA and a non-emission area. The emission area EMA may be an area in which the light emitting element ED is disposed to emit light of a wavelength band. The non-emission area may be a region in which the light emitting element ED is not disposed and a region from which light is not emitted because light emitted from the light emitting element ED does not reach there.

The emission area EMA may include a region in which the light emitting element ED is disposed, and a region adjacent to the light emitting element ED in which the lights emitted from the light emitting element ED are emitted. For example, the emission area EMA may include a region in which the light emitted from the light emitting element ED is reflected or refracted by another member and emitted. The light emitting elements ED may be disposed in each sub-pixel SPXn, and the emission area may include an area where the light emitting elements ED are disposed and an area adjacent thereto.

The sub-pixel SPXn may further include a sub-region SA disposed in the non-emission area. The sub-region SA of the corresponding sub-pixel SPXn may be disposed on the lower side of the emission area EMA, which is another side in the first direction DR1. The emission area EMA and the sub-region SA may be alternately arranged in the first direction DR1, and the sub-region SA may be disposed between the emission areas EMA of different sub-pixels SPXn spaced apart from each other in the first direction DR1. For example, the emission area EMA and the sub-region SA may be alternately arranged in the first direction DR1, and each of the emission area EMA and the sub-region SA may be repeatedly arranged in the second direction DR2.

Light may not be emitted from the sub-region SA because the light emitting element ED is not disposed in the sub-region SA, but a portion of the electrode RME in a sub-pixel SPXn may be disposed in the sub-region SA. The electrodes RME disposed in different sub-pixels SPXn may be separated at a separation portion ROP of the sub-region SA.

Wires and circuit elements of the circuit layer disposed in the sub-pixel SPXn may be connected to the light emitting element ED. However, the wires and the circuit elements may not be disposed to correspond to the area occupied by the sub-pixel SPXn or the emission area EMA, and may be disposed regardless of the position of the emission area EMA.

The bank layer BNL may surround the sub-pixel SPXn, the emission area EMA, and the sub-region SA in a plan view. The bank layer BNL may be disposed at the boundary between the sub-pixels SPXn adjacent in the first direction DR1 and the second direction DR2, and at the boundary between the emission area EMA and the sub-region SA. The sub-pixels SPXn, the emission area EMA, and the sub-region SA of the display device 10 may be the areas defined by the disposition of the bank layer BNL. The gaps between the sub-pixels SPXn, the emission areas EMA, and the sub-regions SA may vary depending on the width of the bank layer BNL.

The bank layer BNL may include portions extending in the first direction DR1 and the second direction DR2 in a plan view to be arranged in a grid pattern over the entire surface of the display area DPA. The bank layer BNL may be disposed along the boundaries between the sub-pixels SPXn to define the neighboring sub-pixels SPXn. The bank layer BNL may also surround the emission area EMA and the sub-region SA disposed for each sub-pixel SPXn to define the emission area EMA and the sub-region SA from each other.

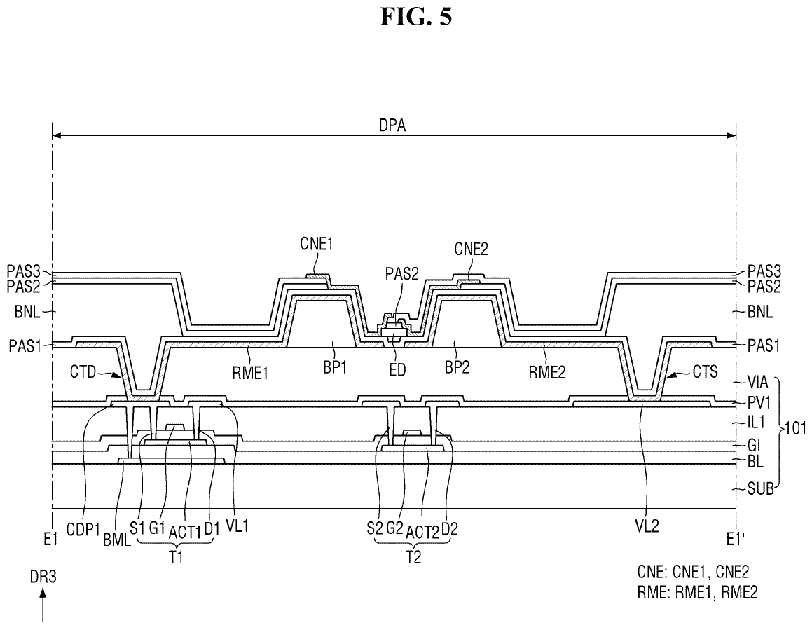

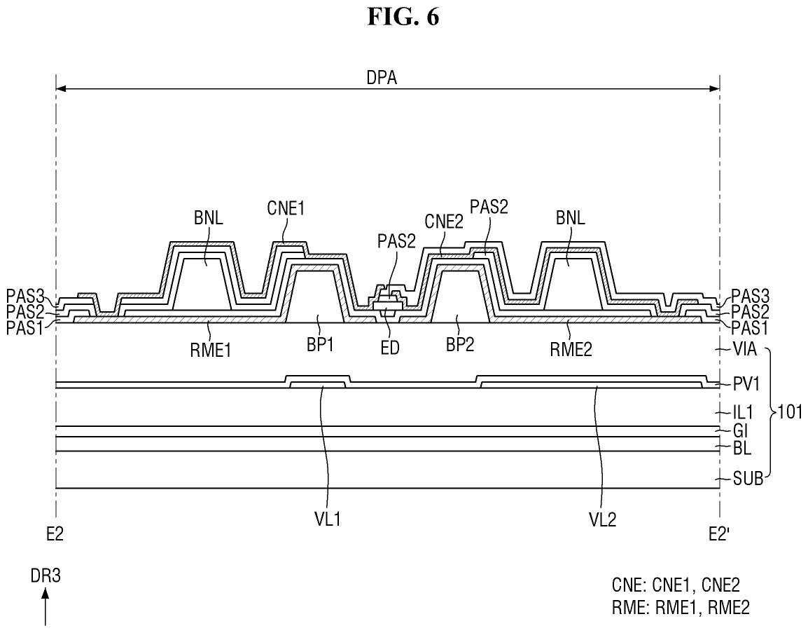

FIG. 5 is a schematic cross-sectional view taken along line E1-E1′ of FIG. 4. FIG. 6 is a schematic cross-sectional view taken along line E2-E2′ of FIG. 4. FIG. 5 schematically illustrates a cross section across ends of the light emitting element ED and electrode contact holes CTD and CTS disposed in the sub-pixel SPXn, and FIG. 6 schematically illustrates a cross section across ends of the light emitting element ED and contact portions CT1 and CT2 disposed in the sub-pixel SPXn.

Referring to FIGS. 5 and 6 in conjunction with FIG. 4, the display device 10 may include a wiring substrate 101 including a first substrate SUB, and a semiconductor layer, multiple conductive layers, and multiple insulating layers that are disposed on the first substrate SUB. Further, the display device 10 may include the electrodes RME (RME1 and RME2), the light emitting element ED, and connection electrodes CNE (CNE1 and CNE2) that are disposed on the wiring substrate 101. The semiconductor layer, the conductive layers, and the insulating layers of the wiring substrate 101 may constitute a circuit layer of the display device 10.

The first substrate SUB may be an insulating substrate. The first substrate SUB may be made of an insulating material such as glass, quartz, or polymer resin. Further, the first substrate SUB may be a rigid substrate, or may be a flexible substrate which can be bent, folded or rolled. The first substrate SUB may include the display area DPA and the non-display area NDA adjacent to the display area DPA, and the display area DPA may include the emission area EMA and the sub-region SA that is a portion of the non-emission area.

A first conductive layer may be disposed on the first substrate SUB. The first conductive layer may include a lower metal layer BML that overlaps a first active layer ACT1 of the first transistor T1 in a plan view. The lower metal layer BML may prevent light from entering the first active layer ACT1 of the first transistor T1, or may be electrically connected to the first active layer ACT1 to stabilize electrical characteristics of the first transistor T1. However, the disclosure is not limited thereto, and in another embodiment, the lower metal layer BML may be omitted.

The buffer layer BL may be disposed on the lower metal layer BML and the first substrate SUB. The buffer layer BL may be formed on the first substrate SUB to protect the transistors of the pixel PX from moisture permeating through the first substrate SUB susceptible to moisture permeation, and may perform a surface planarization function.

The semiconductor layer may be disposed on the buffer layer BL. The semiconductor layer may include the first active layer ACT1 of the first transistor T1 and a second active layer ACT2 of the second transistor T2. The first active layer ACT1 and the second active layer ACT2 may partially overlap a first gate electrode G1 and a second gate electrode G2 of a second conductive layer to be described below in a plan view, respectively.

The semiconductor layer may include at least one of polycrystalline silicon, monocrystalline silicon, oxide semiconductor, and the like. For example, the semiconductor layer may include polycrystalline silicon. The oxide semiconductor may be an oxide semiconductor containing indium (In). For example, the oxide semiconductor may be at least one of indium tin oxide (ITO), indium zinc oxide (IZO), indium gallium oxide (IGO), indium zinc tin oxide (IZTO), indium gallium tin oxide (IGTO), indium gallium zinc oxide (IGZO), and indium gallium zinc tin oxide (IGZTO).

Although it is illustrated in the drawing that one first transistor T1 is disposed in the sub-pixel SPXn of the display device 10, the disclosure is not limited thereto, and the display device 10 may include a larger number of transistors.

The first gate insulating layer GI may be disposed on the semiconductor layer and the buffer layer BL in the display area DPA. The first gate insulating layer GI may not be disposed in the pad area PDA. The first gate insulating layer GI may serve as a gate insulating film of each of the transistors T1 and T2. Although it is illustrated in the drawing that the first gate insulating layer GI is disposed on the entire buffer layer BL, the disclosure is not limited thereto. In some embodiments, the first gate insulating layer GI may be patterned together with the gate electrodes G1 and G2 of the second conductive layer, which will be described below, to be partially disposed between the second conductive layer and the active layers ACT1 and ACT2 of the semiconductor layer.

The second conductive layer may be disposed on the first gate insulating layer GI. The second conductive layer may include a first gate electrode G1 of the first transistor T1 and a second gate electrode G2 of the second transistor T2. The first gate electrode G1 may overlap the channel region of the first active layer ACT1 in a third direction DR3 that is a thickness direction, and the second gate electrode G2 may overlap the channel region of the second active layer ACT2 in the third direction DR3 that is the thickness direction. Although not shown in the drawing, the second conductive layer may further include an electrode of the storage capacitor.

A first interlayer insulating layer IL1 may be disposed on the second conductive layer. The first interlayer insulating layer IL1 may function as an insulating film between the second conductive layer and other layers disposed on the first interlayer insulating layer IL1, and may protect the second conductive layer.

A third conductive layer may be disposed on the first interlayer insulating layer IL1. The third conductive layer may include the first voltage line VL1 and the second voltage line VL2, a first conductive pattern CDP1, a source electrode S1 and a drain electrode D1 of the transistor T1, and a source electrode S2 and a drain electrode D2 of the transistor T2 that are disposed in the display area DPA. Although not shown in the drawing, the third conductive layer may further include another electrode of the storage capacitor.

The first voltage line VL1 may be applied with a high potential voltage (or a first power voltage) transmitted to a first electrode RME1, and the second voltage line VL2 may be applied with a low potential voltage (or a second power voltage) transmitted to a second electrode RME2. A portion of the first voltage line VL1 may be in contact with the first active layer ACT1 of the first transistor T1 through the contact hole penetrating the first interlayer insulating layer IL1 and the first gate insulating layer GI. The first voltage line VL1 may serve as a first drain electrode D1 of the first transistor T1. The second voltage line VL2 may be connected to (e.g., directly connected to) the second electrode RME2 to be described below.

The first conductive pattern CDP1 may be in contact with the first active layer ACT1 of the first transistor T1 through the contact hole penetrating the first interlayer insulating layer IL1 and the first gate insulating layer GI. The first conductive pattern CDP1 may be in contact with the lower metal layer BML through another contact hole. The first conductive pattern CDP1 may serve as a first source electrode S1 of the first transistor T1. Further, the first conductive pattern CDP1 may be connected to the first electrode RME1 or the first connection electrode CNE1 to be described below. The first transistor T1 may transmit the first power voltage applied from the first voltage line VL1 to the first electrode RME1 or the first connection electrode CNE1.

The second source electrode S2 and the second drain electrode D2 may be in contact with the second active layer ACT2 of the second transistor T2 through the contact holes penetrating the first interlayer insulating layer IL1 and the first gate insulating layer GI. The second transistor T2 may be one of the switching transistors described with reference to FIG. 3. The second transistor T2 may transfer the signal applied from the data line DTL of FIG. 3 to the first transistor T1 or may transfer the signal applied from the initialization voltage line VIL of FIG. 3 to another electrode of the storage capacitor.

A first passivation layer PV1 may be disposed on the third conductive layer. The first passivation layer PV1 may function as an insulating layer between the third conductive layer and other layers and may protect the third conductive layer.

The buffer layer BL, the first gate insulating layer GI, the first interlayer insulating layer IL1, and the first passivation layer PV1 described above may be formed of multiple inorganic layers stacked in an alternating manner. For example, the buffer layer BL, the first gate insulating layer GI, the first interlayer insulating layer IL1, and the first passivation layer PV1 may be formed as a double layer formed by stacking, or a multilayer formed by alternately stacking, inorganic layers including at least one of silicon oxide (SiOₓ), silicon nitride (SiNₓ), and silicon oxynitride (SiOₓN_{y}). However, the disclosure is not limited thereto, and in another embodiment, the buffer layer BL, the first gate insulating layer GI, the first interlayer insulating layer IL1, and the first passivation layer PV1 may be formed as a single inorganic layer containing the above-described insulating material. In another embodiment, the first interlayer insulating layer IL1 may be made of an organic insulating material such as polyimide (PI) or the like.

A via layer VIA may be disposed on the third conductive layer in the display area DPA. The via layer VIA may contain an organic insulating material, e.g., polyimide (PI), and may compensate the stepped portion formed by the conductive layers disposed under the via layer VIA to flatten the top surface. However, the disclosure is not limited thereto, and in another embodiment, the via layer VIA may be omitted.

The display device 10 may include, as a display element layer disposed on the via layer VIA of the wiring substrate 101, the bank patterns BP1 and BP2, the electrodes RME (RME1 and RME2), the bank layer BNL, the light emitting elements ED, and the connection electrodes CNE (CNE1 and CNE2). Further, the display device 10 may include multiple insulating layers PAS1, PAS2, and PAS3 disposed on the wiring substrate 101.

The bank patterns BP1 and BP2 may be disposed in the emission area EMA of each sub-pixel SPXn. The bank patterns BP1 and BP2 may have a width in the second direction DR2 and may have a shape extending in the first direction DR1.

For example, the bank patterns BP1 and BP2 may include a first bank pattern BP1 and a second bank pattern BP2 spaced apart from each other in the second direction DR2 in the emission area EMA of each sub-pixel SPXn. The first bank pattern BP1 may be disposed on the left side with respect to the center of the emission area EMA, which is a side in the second direction DR2, and the second bank patterns BP2 may be disposed on the right side with respect to the center of the emission area EMA, which is another side in the second direction DR2, while being spaced apart from the first bank pattern BP1. The first bank pattern BP1 and the second bank pattern BP2 may be alternately disposed in the second direction DR2 and may be arranged in an island-like pattern in the display area DPA. The light emitting elements ED may be disposed between the first bank pattern BP1 and the second bank pattern BP2.

The lengths of the first bank pattern BP1 and the second bank pattern BP2 in the first direction DR1 may be the same, and may be smaller than the length of the emission area EMA surrounded by the bank layer BNL in the first direction DR1. The first bank pattern BP1 and the second bank pattern BP2 may be spaced apart from a portion of the bank layer BNL extending in the second direction DR2. However, the disclosure is not limited thereto, and the bank patterns BP1 and BP2 may be integrated with the bank layer BNL, or may partially overlap the portion of the bank layer BNL extending in the second direction DR2, and the lengths of the bank patterns BP1 and BP2 in the first direction DR1 may be greater than or equal to the length of the emission area EMA surrounded by the bank layer BNL in the first direction DR1.

The widths of the first bank pattern BP1 and the second bank pattern BP2 in the second direction DR2 may be the same. However, the disclosure is not limited thereto, and in another embodiment, the first bank pattern BP1 and the second bank pattern BP2 may have different widths. For example, a bank pattern may have a greater width than another bank pattern, and the bank pattern having a greater width may be disposed across the emission areas EMA of another sub-pixels SPXn adjacent in the second direction DR2. In the bank pattern disposed across the emission areas EMA, a portion of the bank layer BNL extending in the first direction DR1 may overlap the second bank pattern BP2 in the thickness direction. Although it is illustrated in the drawing that two bank patterns BP1 and BP2 having the same width are arranged for each sub-pixel SPXn, the disclosure is not limited thereto. The number and the shape of the bank patterns BP1 and BP2 may vary depending on the number or the disposition structure of the electrodes RME.

The bank patterns BP1 and BP2 may be disposed on the via layer VIA. For example, each of the bank patterns BP1 and BP2 may be disposed on (e.g., directly disposed on) the via layer VIA, and may have a structure in which at least a part protrudes from the top surface of the via layer VIA. The protruding parts of the bank patterns BP1 and BP2 may have inclined or curved side surfaces, and the light emitted from the light emitting element ED may be reflected by the electrode RME disposed on the bank patterns BP1 and BP2 and emitted in the upward direction of the via layer VIA. Unlike the illustrated embodiment in the drawings, the bank patterns BP1 and BP2 may have a shape of a semi-circle or semi-ellipse with outer surface curved in a cross-sectional view. The bank patterns BP1 and BP2 may include an organic insulating material such as polyimide (PI), but the disclosure is not limited thereto.

The electrodes RME (RME1 and RME2) may have a shape extending in a direction and may be disposed for each sub-pixel SPXn. The electrodes RME1 and RME2 may extend in the first direction DR1 across the emission area EMA of the sub-pixel SPXn and the sub-region SA, and may be spaced apart from each other in the second direction DR2. The electrodes RME may be electrically connected to the light emitting element ED to be described below. However, the disclosure is not limited thereto, and in another embodiment, the electrodes RME may not be electrically connected to the light emitting element ED.

The display device 10 may include the first electrode RME1 and the second electrode RME2 arranged in each sub-pixel SPXn. The first electrode RME1 may be located on the left side with respect to the center of the emission area EMA, and the second electrode RME2 may be located on the right side with respect to the center of the emission area EMA while being spaced apart from the first electrode RME1 in the second direction DR2. A first electrode RME1 may be disposed on the first bank pattern BP1, and a second electrode RME2 may be disposed on the second bank pattern BP2. The first electrode RME1 and the second electrode RME2 may be partially arranged in the corresponding sub-pixel SPXn and the sub-region SA over the bank layer BNL. The first electrode RME1 and the second electrode RME2 of adjacent sub-pixels SPXn may be separated at the separation portion ROP located in the sub-region SA of one sub-pixel SPXn.

Although it is illustrated in the drawing that two electrodes RME have a shape extending in the first direction DR1 for each sub-pixel SPXn, the disclosure is not limited thereto. A larger number of electrodes RME may be disposed, or the electrodes RME may be partially bent and have different widths depending on positions.

The first electrode RME1 and the second electrode RME2 may be arranged at least on the inclined surfaces of the bank patterns BP1 and BP2. In one embodiment, the widths of the electrodes RME measured in the second direction DR2 may be smaller than the widths of the bank patterns BP1 and BP2 measured in the second direction DR2, and the gap between the first electrode RME1 and the second electrode RME2 in the second direction DR2 may be smaller than the gap between the bank patterns BP1 and BP2. At least a portion of the first electrode RME1 and the second electrode RME2 may be arranged on (e.g., directly arranged) on the via layer VIA, so that the first electrode RME1 and the second electrode RME2 may be arranged on a same plane.

The light emitting element ED disposed between the bank patterns BP1 and BP2 may emit light toward ends, and the emitted light may be directed toward the electrodes RME disposed on the bank patterns BP1 and BP2. The electrodes RME may have a structure in which portions disposed on the bank patterns BP1 and BP2 may reflect the light emitted from the light emitting element ED. The first electrode RME1 and the second electrode RME2 may be arranged to cover at least one side surfaces of the bank patterns BP1 and BP2 and may reflect the light emitted from the light emitting element ED.

The electrodes RME may be in direct contact with the third conductive layer through the electrode contact holes CTD and CTS at the portions overlapping the bank layer BNL in a plan view between the emission area EMA and the sub-region SA. The first electrode contact hole CTD may be formed in an area in which the bank layer BNL and the first electrode RME1 overlap in a plan view, and the second electrode contact hole CTS may be formed in an area in which the bank layer BNL and the second electrode RME2 overlap in a plan view. The first electrode RME1 may be in contact with the first conductive pattern CDP1 through the first electrode contact hole CTD penetrating the via layer VIA and the first passivation layer PV1. The second electrode RME2 may be in contact with the second voltage line VL2 through the second electrode contact hole CTS penetrating the via layer VIA and the first passivation layer PV1. The first electrode RME1 may be electrically connected to the first transistor T1 through the first conductive pattern CDP1, so that the first power voltage may be applied to the first electrode RME1, and the second electrode RME2 may be electrically connected to the second voltage line VL2, so that the second power voltage may be applied to the second electrode RME2. However, the disclosure is not limited thereto. In another embodiment, the electrodes RME1 and RME2 may not be electrically connected to the voltage lines VL1 and VL2 of the third conductive layer, respectively, and the connection electrode CNE to be described below may be connected to (e.g., directly connected to) the third conductive layer.

The electrodes RME may include a conductive material having high reflectivity. For example, the electrodes RME may include a metal such as silver (Ag), copper (Cu), or aluminum (Al), or may include an alloy including aluminum (Al), nickel (Ni), lanthanum (La), or the like. In another embodiment, the electrodes RME may have a structure in which a metal layer including titanium (Ti), molybdenum (Mo), and niobium (Nb) and an alloy are stacked each other. In an embodiment, the electrodes RME may be formed as a double layer or a multilayer formed by stacking at least one metal layer made of an alloy including aluminum (Al) and titanium (Ti), molybdenum (Mo), and niobium (Nb).

The disclosure is not limited thereto, and each electrode RME may further include a transparent conductive material. For example, each electrode RME may include a material such as ITO, IZO, and ITZO. In some embodiments, each of the electrodes RME may have a structure in which at least one transparent conductive material and at least one metal layer having high reflectivity are stacked each other, or may be formed as one layer including at least one transparent conductive material and at least one metal layer having high reflectivity. For example, each electrode RME may have a stacked structure of ITO/Ag/ITO, ITO/Ag/IZO, ITO/Ag/ITZO/IZO, or the like. The electrodes RME may be electrically connected to the light emitting element ED, and may reflect some of the lights emitted from the light emitting element ED in an upward direction of the first substrate SUB.

A first insulating layer PAS1 may be disposed in the entire display area DPA and may be disposed on the via layer VIA and the electrodes RME. The first insulating layer PAS1 may protect the electrodes RME and insulate the electrodes RME from each other. For example, the first insulating layer PAS1 may be formed to cover the electrodes RME before the bank layer BNL is formed, so that it is possible to prevent the electrodes RME from being damaged in a process of forming the bank layer BNL. The first insulating layer PAS1 may prevent the light emitting element ED from being damaged by direct contact with other members.

In an embodiment, the first insulating layer PAS1 may have stepped portions such that the top surface is partially depressed between the electrodes RME spaced apart in the second direction DR2. The light emitting element ED may be disposed on the top surface of the first insulating layer PAS1, where the stepped portions are formed, and thus a space may be formed between the light emitting element ED and the first insulating layer PAS1.

The bank layer BNL may be disposed on the first insulating layer PAS1. The bank layer BNL may include portions extending in the first direction DR1 and the second direction DR2, and may surround the sub-pixels SPXn in a plan view. The bank layer BNL may surround and define the emission area EMA and the sub-region SA of each sub-pixel SPXn, and may surround the outermost portion of the display area DPA and define the display area DPA and the non-display area NDA. The bank layer BNL may be disposed in the entire display area DPA to form a grid pattern, and the regions exposed by the bank layer BNL in the display area DPA may be the emission area EMA and the sub-region SA.

Similarly to the bank patterns BP1 and BP2, the bank layer BNL may have a height. In some embodiments, the top surface of the bank layer BNL may be higher than the top surfaces of the bank patterns BP1 and BP2, and the thickness of the bank layer BNL may be equal to or greater than the thicknesses of the bank patterns BP1 and BP2. The bank layer BNL may prevent ink from overflowing to adjacent sub-pixels SPXn in an inkjet printing process during the manufacturing process of the display device 10. The bank layer BNL may include an organic insulating material such as polyimide, similarly to the bank patterns BP1 and BP2.

The light emitting elements ED may be arranged in the emission area EMA. The light emitting elements ED may be disposed between the bank patterns BP1 and BP2, and may be arranged to be spaced apart from each other in the first direction DR1. In one embodiment, the light emitting elements ED may have a shape extending in a direction, and ends of the light emitting elements ED may be disposed on different electrodes RME. The length of the light emitting element ED may be greater than the gap between the electrodes RME spaced apart from each other in the second direction DR2. The extension direction of the light emitting elements ED may be substantially perpendicular to the first direction DR1 in which the electrodes RME extend. However, the disclosure is not limited thereto, and the light emitting element ED may extend in the second direction DR2 or in a direction oblique to the second direction DR2.

The light emitting elements ED may be arranged on the first insulating layer PAS1. The light emitting element ED may have a shape extending in a direction, and may be disposed such that the direction in which the light emitting element ED extends is parallel to the top surface of the first substrate SUB. As will be described below, the light emitting element ED may include multiple semiconductor layers arranged along a direction in which the light emitting element ED extends, and the semiconductor layers may be sequentially arranged along the direction parallel with the top surface of the first substrate SUB. However, the disclosure is not limited thereto, and the semiconductor layers may be arranged in the direction perpendicular to the first substrate SUB in case that the light emitting element ED has another structure.

The light emitting elements ED disposed in each sub-pixel SPXn may emit light of different wavelength bands depending on a material constituting the semiconductor layer. However, the disclosure is not limited thereto, and the light emitting elements ED arranged in each sub-pixel SPXn may include the semiconductor layer of a same material and emit light of a same color.

The light emitting elements ED may be electrically connected to the electrode RME and the conductive layers below the via layer VIA while being in contact with the connection electrodes CNE (CNE1 and CNE2), and may emit light of a wavelength band by receiving an electrical signal.

A second insulating layer PAS2 may be disposed on the light emitting elements ED, the first insulating layer PAS1, and the bank layer BNL. The second insulating layer PAS2 may include a pattern portion disposed on the light emitting elements ED while extending in the first direction DR1 between the bank patterns BP1 and BP2. The pattern portion may partially surround the outer surface of the light emitting element ED, and may not cover entire sides or ends of the light emitting element ED. The pattern portion may form a linear or island-like pattern in each sub-pixel SPXn in a plan view. The pattern portion of the second insulating layer PAS2 may protect the light emitting element ED and fix the light emitting elements ED during a manufacturing process of the display device 10. Further, the second insulating layer PAS2 may fill the space between the light emitting element ED and the first insulating layer PAS1. Further, a portion of the second insulating layer PAS2 may be disposed on the bank layer BNL and in the sub-regions SA.

The connection electrodes CNE (CNE1 and CNE2) may be disposed on the electrodes RME and the bank patterns BP1 and BP2. The connection electrodes CNE may have a shape extending in a direction, and may be disposed to be spaced apart from each other. Each of the connection electrodes CNE may be in contact with the light emitting element ED, and may be electrically connected to the third conductive layer.

The connection electrodes CNE may include the first connection electrode CNE1 and the second connection electrode CNE2 disposed in each sub-pixel SPXn. The first connection electrode CNE1 may have a shape extending in the first direction DR1 and may be disposed on the first electrode RME1 or the first bank pattern BP1. The first connection electrode CNE1 may partially overlap the first electrode RME1 in a plan view and may be disposed across the emission area EMA and the sub-region SA over the bank layer BNL. The second connection electrode CNE2 may have a shape extending in the first direction DR1 and may be disposed on the second electrode RME2 or the second bank pattern BP2. The second connection electrode CNE2 may partially overlap the second electrode RME2 in a plan view and may be disposed across the emission area EMA and the sub-region SA over the bank layer BNL. Each of the first connection electrode CNE1 and the second connection electrode CNE2 may be in contact with the light emitting elements ED, and may be electrically connected to the electrodes RME or the conductive layer disposed under the first connection electrode CNE1 and the second connection electrode CNE2.

For example, the first connection electrode CNE1 and the second connection electrode CNE2 may be disposed on side surfaces of the second insulating layer PAS2 and may be in contact with the light emitting elements ED. The first connection electrode CNE1 may partially overlap the first electrode RME1 in a plan view and may be in contact with ends of the light emitting elements ED. The second connection electrode CNE2 may partially overlap the second electrode RME2 in a plan view and may be in contact with another ends of the light emitting elements ED. The connection electrodes CNE may be disposed across the emission area EMA and the sub-region SA. The connection electrodes CNE may be in contact with the light emitting elements ED at portions disposed in the emission area EMA, and may be electrically connected to the third conductive layer at portions disposed in the sub-region SA.

In accordance with one embodiment, in the display device 10, the connection electrodes CNE may be in contact with the electrode RME through the contact portions CT1 and CT2 disposed in the sub-region SA. The first connection electrode CNE1 may be in contract with the first electrode RME1 through the first contact portion CT1 penetrating the first insulating layer PAS1, the second insulating layer PAS2, and a third insulating layer PAS3 in the sub-region SA. The second connection electrode CNE2 may be in contact with the second electrode RME2 through the second contact portion CT2 penetrating the first insulating layer PAS1 and the second insulating layer PAS2 in the sub-region SA. Each of the connection electrodes CNE may be electrically connected to the third conductive layer through each of electrodes RME. The first connection electrode CNE1 may be electrically connected to the first transistor T1, so that the first power voltage may be applied to the first connection electrode CNE1, and the second connection electrode CNE2 may be electrically connected to the second voltage line VL2, so that the second power voltage may be applied to the second connection electrode CNE2. Each connection electrode CNE may be in contact with the light emitting element ED in the emission area EMA to transmit the power voltage to the light emitting element ED.

However, the disclosure is not limited thereto. In some embodiments, the connection electrodes CNE may be in direct contact with the third conductive layer, and may be electrically connected to the third conductive layer through patterns other than the electrodes RME.

The connection electrodes CNE may include a conductive material. For example, the connection electrodes CNE may include ITO, IZO, ITZO, aluminum (Al), or the like. For example, the connection electrodes CNE may include a transparent conductive material, and light emitted from the light emitting element ED may pass through the connection electrodes CNE to be emitted.

The third insulating layer PAS3 may be disposed on the second connection electrode CNE2 and the second insulating layer PAS2. The third insulating layer PAS3 may be disposed on the entire second insulating layer PAS2 to cover the second connection electrode CNE2, and the first connection electrode CNE1 may be disposed on the third insulating layer PAS3. The third insulating layer PAS3 may be disposed on the entire via layer VIA except the region where the second connection electrode CNE2 is disposed. The third insulating layer PAS3 may insulate the first connection electrode CNE1 and the second connection electrode CNE2 to prevent direct contact between the first connection electrode CNE1 and the second connection electrode CNE2.

Although not illustrated in the drawings, another insulating layer may be further disposed on the third insulating layer PAS3 and the first connection electrode CNE1. The insulating layer may function to protect the members disposed on the first substrate SUB against the external environment.

Each of the first insulating layer PAS1, the second insulating layer PAS2 and the third insulating layer PAS3 described above may include an inorganic insulating material or an organic insulating material. For example, each of the first insulating layer PAS1, the second insulating layer PAS2, and the third insulating layer PAS3 may include an inorganic insulating material, or the first insulating layer PAS1 and the third insulating layer PAS3 may include an inorganic insulating material and the second insulating layer PAS2 may include an organic insulating material. Each or at least one of the first insulating layer PAS1, the second insulating layer PAS2, and the third insulating layer PAS3 may have a structure in which multiple insulating layers are stacked each other alternately or repeatedly. In an embodiment, each of the first insulating layer PAS1, the second insulating layer PAS2, and the third insulating layer PAS3 may include at least one of silicon oxide (SiOₓ), silicon nitride (SiNₓ), and silicon oxynitride (SiOₓN_{y}). The first insulating layer PAS1, the second insulating layer PAS2, and the third insulating layer PAS3 may be made of a same material or different materials. In another embodiment, some of the first insulating layer PAS1, the second insulating layer PAS2, and the third insulating layer PAS3 may be made of a same material and some of the first insulating layer PAS1, the second insulating layer PAS2, and the third insulating layer PAS3 may be made of different materials.

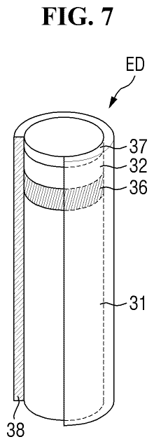

FIG. 7 is a schematic perspective view of a light emitting element according to one embodiment.

Referring to FIG. 7, the light emitting element ED may be a light emitting diode. For example, the light emitting element ED may be an inorganic light emitting diode that has a nanometer or micrometer size, and is made of an inorganic material. The light emitting element ED may be aligned between two electrodes having polarity in case that an electric field is formed in a direction between two electrodes facing each other.

The light emitting element ED according to one embodiment may have a shape elongated in a direction. The light emitting element ED may have a shape of a cylinder, a rod, a wire, a tube, or the like. However, the shape of the light emitting element ED is not limited thereto, and in another embodiment, the light emitting element ED may have a polygonal prism shape such as a regular cube, a rectangular parallelepiped and a hexagonal prism, or may have various shapes such as a shape elongated in a direction and having an outer surface partially inclined.

The light emitting element ED may include a semiconductor layer doped with a conductivity type (e.g., p-type or n-type) dopant. The semiconductor layer may emit light of a wavelength band by receiving an electrical signal applied from an external power source. The light emitting element ED may include a first semiconductor layer 31, a second semiconductor layer 32, a light emitting layer 36, an electrode layer 37 and an insulating film 38.

The first semiconductor layer 31 may be an n-type semiconductor. The first semiconductor layer 31 may include a semiconductor material having a chemical formula of AlₓGa_{y}In_{1-x-y}N (0≤x≤1, 0≤y≤1, 0≤x+y≤1). For example, the first semiconductor layer 31 may include one or more of AlGaInN, GaN, AlGaN, InGaN, AlN and InN doped with an n-type dopant. The n-type dopant doped into the first semiconductor layer 31 may be Si, Ge, Se, Sn, or the like.

The second semiconductor layer 32 may be disposed on the first semiconductor layer 31 with the light emitting layer 36 between the second semiconductor layer 32 and the first semiconductor layer 31. The second semiconductor layer 32 may be a p-type semiconductor, and the second semiconductor layer 32 may include a semiconductor material having a chemical formula of AlₓGa_{y}In_{1-x-y}N (0≤x≤1, 0≤y≤1, 0≤x+y≤1). For example, the second semiconductor layer 32 may include one or more of AlGaInN, GaN, AlGaN, InGaN, AlN and InN doped with a p-type dopant. The p-type dopant doped into the second semiconductor layer 32 may be Mg, Zn, Ca, Ba, or the like.

Although it is illustrated in the drawing that the first semiconductor layer 31 and the second semiconductor layer 32 are configured as one layer, the disclosure is not limited thereto. Depending on the material of the light emitting layer 36, the first semiconductor layer 31 and the second semiconductor layer 32 may further include a greater number of layers, such as a cladding layer or a tensile strain barrier reducing (TSBR) layer. For example, the light emitting element ED may further include another semiconductor layer disposed between the first semiconductor layer 31 and the light emitting layer 36 or between the second semiconductor layer 32 and the light emitting layer 36. The semiconductor layer disposed between the first semiconductor layer 31 and the light emitting layer 36 may include one or more of AlGaInN, GaN, AlGaN, InGaN, AlN, InN and SLs doped with an n-type dopant, and the semiconductor layer disposed between the second semiconductor layer 32 and the light emitting layer 36 may include one or more of AlGaInN, GaN, AlGaN, InGaN, AlN and InN doped with a p-type dopant.

The light emitting layer 36 may be disposed between the first semiconductor layer 31 and the second semiconductor layer 32. The light emitting layer 36 may include a material having a single or multiple quantum well structure. In case that the light emitting layer 36 includes a material having a multiple quantum well structure, multiple quantum layers and well layers may be alternately stacked each other. The light emitting layer 36 may emit light by coupling of electron-hole pairs according to an electrical signal applied through the first semiconductor layer 31 and the second semiconductor layer 32. The light emitting layer 36 may include a material such as AlGaN, AlGaInN, or InGaN. For example, in case that the light emitting layer 36 has a multiple quantum well structure in which quantum layers and well layers are alternately stacked each other, the quantum layer may include a material such as AlGaN or AlGaInN, and the well layer may include a material such as GaN or AlInN.

The light emitting layer 36 may have a structure in which semiconductor materials having large band gap energy and semiconductor materials having small band gap energy are alternately stacked each other, and may include group III to V semiconductor materials according to the wavelength band of the emitted light. The light emitted by the light emitting layer 36 is not limited to the light of the blue wavelength band, and the light emitting layer 36 may emit light of a red or green wavelength band in another embodiment.

The electrode layer 37 may be an ohmic connection electrode. However, the disclosure is not limited thereto, and the electrode layer 37 may be a Schottky connection electrode. The light emitting element ED may include at least one electrode layer 37. The light emitting element ED may include one or more electrode layers 37, but the disclosure is not limited thereto, and in another embodiment, the electrode layer 37 may be omitted.

In the display device 10, in case that the light emitting element ED is electrically connected to an electrode or a connection electrode, the electrode layer 37 may reduce the resistance between the light emitting element ED and the electrode or connection electrode. The electrode layer 37 may include a conductive metal. For example, the electrode layer 37 may include at least one of aluminum (Al), titanium (Ti), indium (In), gold (Au), silver (Ag), ITO, IZO, and ITZO.

The insulating film 38 may be arranged to surround the outer surfaces of the semiconductor layers and electrode layers described above. For example, the insulating film 38 may surround at least the outer surface of the light emitting layer 36, and may be formed to expose ends of the light emitting element ED in the longitudinal direction. Further, in a cross-sectional view, the insulating film 38 may have a top surface, which is rounded in a region adjacent to at least one end of the light emitting element ED.

The insulating film 38 may include at least one of materials having insulating properties, for example, silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), or titanium oxide (TiOₓ). It is illustrated in the drawing that the insulating film 38 is formed as a single layer, but the disclosure is not limited thereto. In some embodiments, the insulating film 38 may be formed in a multilayer structure having multiple layers stacked each other.

The insulating film 38 may perform a function of protecting the semiconductor layers and the electrode layer of the light emitting element ED. The insulating film 38 may prevent an electrical short circuit that may occur at the light emitting layer 36 in case that an electrode to which an electrical signal is transmitted is in direct contact with the light emitting element ED. The insulating film 38 may prevent a decrease in luminous efficiency of the light emitting element ED.

Further, the insulating film 38 may have an outer surface which is surface-treated. The light emitting elements ED may be aligned by spraying the ink in which the light emitting elements ED are dispersed on the electrodes. The surface of the insulating film 38 may be treated to have a hydrophobic property or hydrophilic property in order to keep the light emitting elements ED in the dispersed state without being aggregated with other adjacent light emitting elements ED in the ink.

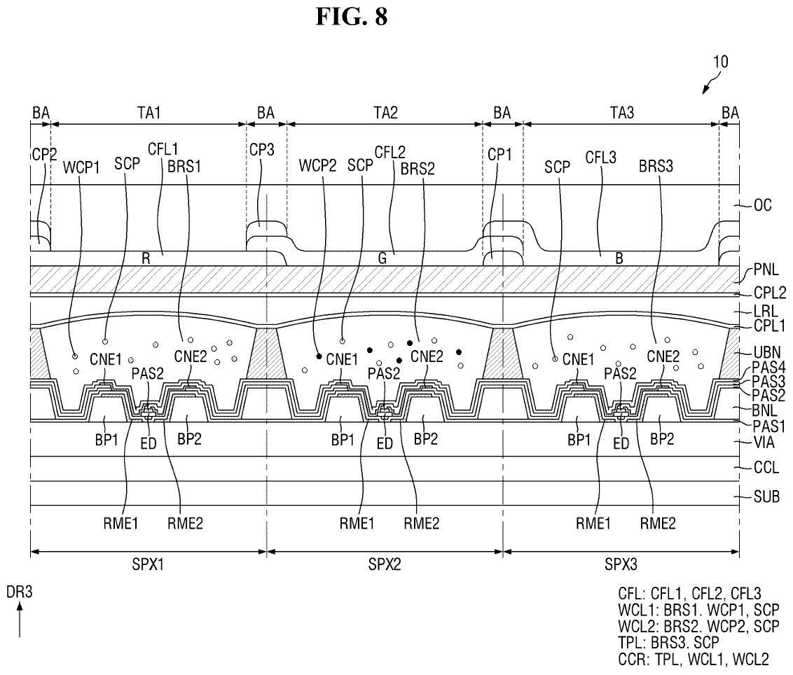

According to one embodiment, the display device 10 may further include a color control layer (‘CCR’ in FIG. 8) and a color filter layer (‘CFL’ in FIG. 8) disposed on the light emitting elements ED. Light emitted from the light emitting element ED may be emitted through a color control layer CCR and a color filter layer CFL. Even if the same type of the light emitting elements ED are disposed in the respective sub-pixels SPXn, the color of the emitted light may be different for each sub-pixel SPXn.

FIG. 8 is a schematic cross-sectional view of a display device according to one embodiment.

Referring to FIG. 8, the display device 10 may include the light emitting elements ED disposed on the substrate SUB, and the color control layer CCR and the color filter layer CFL may be disposed on the light emitting elements ED. The display device 10 may further include multiple layers disposed between the color control layer CCR and the color filter layer CFL. Hereinafter, the layers disposed on the light emitting elements ED of the display device 10 will be described.

A fourth insulating layer PAS4 may be disposed on the third insulating layer PAS3, the connection electrodes CNE1 and CNE2, and the bank layer BNL. The fourth insulating layer PAS4 may protect the layers disposed on the substrate SUB. However, the disclosure is not limited thereto, and in another embodiment, the fourth insulating layer PAS4 may be omitted.

An upper bank layer UBN, the color control layer CCR, color patterns CP1, CP2 and CP3, and the color filter layer CFL may be disposed on the fourth insulating layer PAS4. Multiple capping layers CPL1 and CPL2, a low refractive layer LRL, and a planarization layer PNL may be disposed between the color control layer CCR and the color filter layer CFL. An overcoat layer OC may be disposed on the color filter layer CFL.

The display device 10 may include light transmitting areas TA1, TA2, and TA3 in which the color filter layer CFL is disposed to emit light and a light blocking area BA disposed between the light transmitting areas TA1, TA2 and TA3 and in which light is not emitted. The light transmitting areas TA1, TA2, and TA3 may be located to correspond to a portion of the emission area EMA of each sub-pixel SPXn, and the light blocking area BA may be an area other than the light transmitting areas TA1, TA2, and TA3.

The upper bank layer UBN may be disposed on the fourth insulating layer PAS4 and overlap the bank layer BNL in a plan view. The upper bank layer UBN may include portions extending in the first and second directions DR1 and DR2 and may be disposed in a grid pattern. The upper bank layer UBN may surround the emission area EMA or a portion in which the light emitting elements ED are arranged in a plan view. The upper bank layer UBN may form a region in which the color control layer CCR is disposed.

The color control layer CCR may be disposed in a region surrounded by the upper bank layer UBN on the fourth insulating layer PAS4. The color control layer CCR may be disposed in the light transmitting areas TA1, TA2, and TA3 surrounded by the upper bank layer UBN to form an island-like pattern in the display area DPA. However, the disclosure is not limited thereto, and each of the color control layers CCR may extend in a direction and may be disposed across the sub-pixels SPXn to form a linear pattern.

In an embodiment in which the light emitting element ED of each sub-pixel SPXn emits blue light of the third color, the color control layer CCR may include a first wavelength conversion layer WCL1 disposed in a first sub-pixel SPX1 to correspond to a first light transmitting area TA1, a second wavelength conversion layer WCL2 disposed in a second sub-pixel SPX2 to correspond to a second light transmitting area TA2, and a light transmitting layer TPL disposed in a third sub-pixel SPX3 to correspond to a third light transmitting area TA3.

The first wavelength conversion layer WCL1 may include a first base resin BRS1 and a first wavelength conversion material WCP1 provided in the first base resin BRS1. The second wavelength conversion layer WCL2 may include a second base resin BRS2 and a second wavelength conversion material WCP2 provided in the second base resin BRS2. The first wavelength conversion layer WCL1 and the second wavelength conversion layer WCL2 may convert the blue light of the third color incident from the light emitting element ED. The first wavelength conversion layer WCL1 and the second wavelength conversion layer WCL2 may further include a scatterer SCP contained in each base resin, and the scatterer SCP may increase wavelength conversion efficiency.

The light transmitting layer TPL may include a third base resin BRS3 and the scatterer SCP contained in the third base resin BSR3. The light transmitting layer TPL may transmit the blue light of the third color incident from the light emitting element ED while maintaining the wavelength. The scatterer SCP of the light transmitting layer TPL may serve to control an emission path of the light emitted through the light transmitting layer TPL. The light transmitting layer TPL may not include a wavelength conversion material.

The scatterer SCP may be a metal oxide particle or an organic particle. Examples of the metal oxide may include titanium oxide (TiO₂), zirconium oxide (ZrO₂), aluminum oxide (Al₂O₃), indium oxide (In₂O₃), zinc oxide (ZnO), tin oxide (SnO₂), and the like. Examples of a material of the organic particles may include an acrylic resin, an urethane resin, and the like.

The first to third base resins BRS1, BRS2, and BRS3 may include a light transmitting organic material. For example, the first to third base resins BRS1, BRS2, and BRS3 may include an epoxy resin, an acrylic resin, a cardo resin, an imide resin, or the like. The first to third base resins BRS1, BRS2 and BRS3 may be formed of a same material, but the disclosure is not limited thereto.

The first wavelength conversion material WCP1 may convert the blue light of the third color into the red light of the first color, and the second wavelength conversion material WCP2 may convert the blue light of the third color into the green light of the second color. The first wavelength conversion material WCP1 and the second wavelength conversion material WCP2 may be quantum dots, quantum bars, phosphors or the like. Examples of the quantum dot may include group IV nanocrystal, group II-VI compound nanocrystal, group III-V compound nanocrystal, group IV-VI nanocrystal, and a combination thereof.

In some embodiments, the color control layer CCR may be formed by an inkjet printing process or a photoresist process. The color control layer CCR may be formed through drying or exposure and development processes after a material constituting the color control layer CCR is sprayed into or coated on the region surrounded by the upper bank layer UBN. For example, in an embodiment in which the color control layer CCR is formed by an inkjet printing process, the top surface of each color control layer CCR may be formed to be curved, so that the edge portion of each color control layer CCR adjacent to the upper bank layer UBN may be lower than the center portion of each color control layer CCR. However, the disclosure is not limited thereto. In an embodiment in which the color control layer CCR is formed by a photoresist process, the top surface of each color control layer CCR may be formed to be flat, so that the edge portion adjacent to the upper bank layer UBN may be parallel to the top surface of the upper bank layer UBN. In another embodiment, unlike the drawing, the center portion of the color control layer CCR may be formed to be lower than the edge portion thereof.

The light emitting element ED of each sub-pixel SPXn may emit the blue light of the same third color, and the sub-pixels SPXn may emit lights of different colors. For example, the light emitted from the light emitting element ED disposed in the first sub-pixel SPX1 may be incident on the first wavelength conversion layer WCL1, the light emitted from the light emitting element ED disposed in the second sub-pixel SPX2 may be incident on the second wavelength conversion layer WCL2, and the light emitted from the light emitting element ED disposed in the third sub-pixel SPX3 may be incident on the light transmitting layer TPL.

The light incident on the first wavelength conversion layer WCL1 may be converted into red light, the light incident on the second wavelength conversion layer WCL2 may be converted into green light, and the light incident on the light transmitting layer TPL may be transmitted as the same blue light without wavelength conversion. Although each sub-pixel SPXn includes the light emitting elements ED which emit light of a same color, light of different colors may be emitted according to the disposition of the color control layers CCR disposed above the light emitting elements ED.

The first capping layer CPL1 may be disposed on the color control layer CCR and the upper bank layer UBN. The first capping layer CPL1 may prevent impurities such as moisture or air from permeating from the outside and damaging or contaminating the color control layer CCR. The first capping layer CPL1 may contain an inorganic insulating material.

The low refractive layer LRL may be disposed on the first capping layer CPL1. The low refractive layer LRL that is an optical layer for recycling the light having transmitted the color control layer CCR may improve the light emission efficiency and the color purity of the display device 10. The low refractive layer LRL may be made of an organic material having a low refractive index, and may compensate a stepped portion formed by the color control layer CCR and the upper bank layer UBN.

The second capping layer CPL2 may be disposed on the low refractive layer LRL, and may prevent impurities such as moisture, air or the like from permeating from the outside and damaging or contaminating the low refractive layer LRL. The second capping layer CPL2 may include an inorganic insulating material similarly to the first capping layer CPL1.

The planarization layer PNL may be disposed across the entire display area DPA and the entire non-display area NDA on the second capping layer CPL2. The planarization layer PNL may overlap the color control layer CCR in a plan view in the display area DPA, and may overlap a dam in a plan view, which will be described below, in the non-display area NDA.

The planarization layer PNL may protect the members disposed on the substrate SUB in addition to the capping layers CPL1 and CPL2 and the low refractive layer LRL, and may partially compensate the stepped portion formed under the planarization layer PNL. For example, the planarization layer PNL may compensate the stepped portion formed by the color control layer CCR, the upper bank layer UBN, and the bank layer BNL under the planarization layer PNL in the display area DPA. Therefore, the color filter layer CFL disposed on the planarization layer PNL may be formed on a planar surface.

The color filter layer CFL may be disposed on the planarization layer PNL. The color filter layer CFL may be disposed in the light transmitting areas TA1, TA2, and TA3, and a part of the color filter layer CFL may be disposed in the light blocking area BA. The portion of the color filter layer CFL may overlap another part of the color filter layer CFL or the color patterns CP1, CP2, and CP3 in the light blocking area BA. A portion where the color filter layers CFL do not overlap each other may be the light transmitting area TA1, TA2, or TA3 from which light is emitted. An area where the color filter layers CFL overlap each other or where the color patterns CP1, CP2, and CP3 are disposed may be the light blocking area BA in which light is blocked.

The color filter layer CFL may include a first color filter CFL1 disposed in the first sub-pixel SPX1, a second color filter CFL2 disposed in the second sub-pixel SPX2, and a third color filter CFL3 disposed in the third sub-pixel SPX3. Each of the color filters CFL1, CFL2, and CFL3 may be formed in a linear pattern disposed in the light transmitting areas TA1, TA2, and TA3 or the emission areas EMA. However, the disclosure is not limited thereto. The color filters CFL1, CFL2, and CFL3 may be disposed to correspond to the light transmitting areas TA1, TA2, and TA3, respectively, and may form an island-like pattern.

The color filter layer CFL may contain a colorant such as a dye or a pigment that absorbs light of a wavelength band other than a specific wavelength band. Each of the color filters CFL1, CFL2, and CFL3 may be disposed for each sub-pixel SPXn and may transmit only a portion of light incident on each of the color filters CFL1, CFL2 and CFL3 in the corresponding sub-pixel SPXn. In each sub-pixel SPXn of the display device 10, only light transmitted through each of the color filters CFL1, CFL2, and CFL3 may be selectively displayed. In an embodiment, the first color filter CFL1 may be a red color filter layer, the second color filter CFL2 may be a green color filter layer, and the third color filter CFL3 may be a blue color filter layer. Lights emitted from the light emitting element ED may be emitted through the color control layer CCR and the color filter layer CFL.

The color patterns CP1, CP2, and CP3 may be disposed on the planarization layer PNL or the color filter layer CFL. The color patterns CP1, CP2, and CP3 and the color filter layer CFL may be made of a same material, and the color patterns CP1, CP2, and CP3 may be disposed in the light blocking area BA. In the light blocking area BA, the color patterns CP1, CP2, CP3 and the different color filters CFL1, CFL2, and CFL3 may be stacked each other, and light may be blocked in the stacked area.

The first color pattern CP1 and the first color filter CFL1 may be made of a same material, and the first color pattern CP1 may be disposed in the light blocking area BA. The first color pattern CP1 may be disposed on (e.g., directly disposed) on the planarization layer PNL in the light blocking area BA, and may not be disposed in the light blocking area BA adjacent to the first light transmitting area TA1 of the first sub-pixel SPX1. The first color pattern CP1 may be disposed in the light blocking area BA between the second sub-pixel SPX2 and the third sub-pixel SPX3. The first color filter CFL1 may be disposed in the light blocking area BA adjacent to the first sub-pixel SPX1.

The second color pattern CP2 and the second color filter CFL2 may be made of a same material. and the second color pattern CP2 may be disposed in the light blocking area BA. The second color pattern CP2 may be disposed on (e.g., directly disposed on) the planarization layer PNL in the light blocking area BA, and may not be disposed in the light blocking area BA adjacent to the second light transmitting area TA2 of the second sub-pixel SPX2. The second color pattern CP2 may be disposed in the light blocking area BA between the first sub-pixel SPX1 and the third sub-pixel SPX3, or on a boundary between the non-display area NDA and the outermost sub-pixel SPXn of the display area DPA. The second color filter CFL2 may be disposed in the light blocking area BA adjacent to the second sub-pixel SPX2.

Similarly, the third color pattern CP3 and the third color filter CFL3 may be made of a same material, and the third color pattern CP3 may be disposed in the light blocking area BA. The third color pattern CP3 may be disposed on (e.g., directly disposed on) the planarization layer PNL in the light blocking area BA, and may not be disposed in the light blocking area BA adjacent to the third light transmitting area TA3 of the third sub-pixel SPX3. The third color pattern CP3 may be disposed in the light blocking area BA between the first sub-pixel SPX1 and the second sub-pixel SPX2. The third color filter CFL3 may be disposed in the light blocking area BA adjacent to the third sub-pixel SPX3.

In the display device 10, an area where the bank layer BNL and the upper bank layer UBN overlap each other may be the light blocking area BA. In the light blocking area BA, each of the first color pattern CP1, the second color pattern CP2, and the third color pattern CP3 may be disposed to overlap at least one of the color filters CFL1, CFL2, and CFL3, which contains different color materials. For example, the first color pattern CP1 may overlap the second color filter CFL2 and the third color filter CFL3 in a plan view, the second color pattern CP2 may overlap the first color filter CFL1 and the third color filter CFL3 in a plan view, and the third pattern CP3 may overlap the first color filter CFL1 and the second color filter CFL2 in a plan view. In the light blocking area BA, the color patterns CP1, CP2, and CP3, and the color filters CFL1, CFL2, and CFL3, which contain different color materials, may overlap each other, thereby blocking light.

The color patterns CP1, CP2, and CP3 and the color filters CFL1, CFL2, and CFL3 may constitute the stacked structure and include a material containing different color materials, thereby preventing the color mixture between adjacent areas. As the color patterns CP1, CP2, and CP3 and the color filters CFL1, CFL2, and CFL3 include a same material, external light or reflected light, which has passed through the light blocking area BA, may have a wavelength band of a specific color. The color sensibility perceived by user's eyes may depend on the color of the light. For example, the light in the blue wavelength band may be perceived less sensitively to a user than the light in the green wavelength band and the light in the red wavelength band. In the display device 10, since the color patterns CP1, CP2, and CP3 are disposed in the light blocking area BA, the transmission of the light may be blocked and the user may perceive the reflected light relatively less sensitively. Also, it may be possible to absorb a portion of the light from the outside of the display device 10 and reduce the reflected light due to the external light.

The overcoat layer OC may be disposed on the color filter layer CFL and the color patterns CP1, CP2, and CP3. The overcoat layer OC may be disposed in the entire display area DPA, and may be partially disposed in the non-display area NDA. The overcoat layer OC may protect the members containing an organic insulating material and arranged in the display area DPA from the outside.

The display device 10 according to one embodiment may include the color control layer CCR and the color filter layer CFL disposed above the light emitting elements ED. Therefore, even if the same type of the light emitting elements ED are disposed for each sub-pixel SPXn, the display device 10 may display light of different colors.

For example, the light emitting element ED disposed in the first sub-pixel SPX1 may emit the blue light of the third color, and the light may be incident on the first wavelength conversion layer WCL1 while passing through the fourth insulating layer PAS4. The first base resin BRS1 of the first wavelength conversion layer WCL1 may be made of a transparent material, and a portion of the light may pass through the first base resin BRS1 and be incident on the first capping layer CPL1 disposed on the first base resin BRS1. However, at least a portion of the light may be incident on the scatterer SCP and the first wavelength conversion material WCP1 arranged in the first base resin BRS1. The light may be scattered and subjected to wavelength conversion, and may be incident as red light on the first capping layer CPL1. The lights incident on the first capping layer CPL1 may be incident on the first color filter CFL1 while passing through the low refractive layer LRL, the second capping layer CPL2, and the planarization layer PNL, and the transmission of other lights except the red light may be blocked by the first color filter CFL1. Accordingly, the first sub-pixel SPX1 may emit the red light.

Similarly, the lights emitted from the light emitting element ED disposed in the second sub-pixel SPX2 may be emitted as the green light while passing through the fourth insulating layer PAS4, the second wavelength conversion layer WCL2, the first capping layer CPL1, the low refractive layer LRL, the second capping layer CPL2, the planarization layer PNL, and the second color filter CFL2.

The light emitting element ED disposed in the third sub-pixel SPX3 may emit the blue light of the third color, and the blue light may be incident on the light transmitting layer while passing through the fourth insulating layer PAS4. The third base resin BRS3 of the light transmitting layer TPL may be made of a transparent material, and a portion of the light may transmit the third base resin BRS3 and be incident on the capping layer CPL1 disposed on the third base resin BRS3. The lights incident on the first capping layer CPL1 may be incident on the third color filter CFL3 while passing through the low refractive layer LRL, the second capping layer CPL2, and the planarization layer PNL, and the transmission of other lights except the blue light may be blocked by the third color filter CFL3. Accordingly, the third sub-pixel SPX3 may emit the blue light.

The display device 10 may align the light emitting elements ED by applying an alignment signal to the first and second electrodes RME1 and RME2, and separate the first and second electrodes RME1 and RME2 on a sub-pixel basis. Since the sub-pixels SPXn emitting light of a same color are disposed in the first direction DR1 with the first and second electrodes RME1 and RME2 extending in the first direction DR1, and the sub-pixels SPXn emitting at least three colors need to be disposed, large numbers of the first and second electrodes RME1 and RME2 are required. Hereinafter, the display device 10 according to an embodiment, which is capable of reducing the numbers of the first and second electrodes RME1 and RME2 by arranging the sub-pixels SPXn emitting light of two or more colors with the first and second electrodes RME1 and RME2, will be described. In the following description, the reference numeral of the first electrode RME1 will be indicated as “FRM,” and the reference numeral of the second electrode RME2 will be indicated as “SRM.”

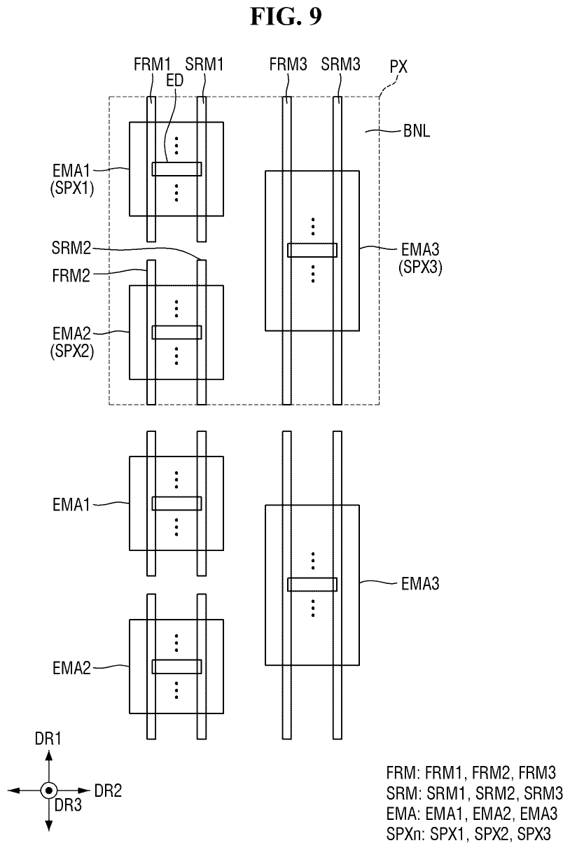

FIG. 9 is a plan view illustrating multiple pixels of a display device according to one embodiment. FIG. 9 shows a planar disposition of electrodes FRM and SRM, the bank layer BNL, the light emitting elements ED, and the emission areas EMA1, EMA2, and EMA3 disposed in the pixels PX of the display device 10.

Referring to FIG. 9, each of the pixels PX of the display device 10 may include multiple sub-pixels SPXn. For example, a pixel PX may include the first sub-pixel SPX1, the second sub-pixel SPX2, and the third sub-pixel SPX3. The first sub-pixel SPX1 may emit light of a first color, the second sub-pixel SPX2 may emit light of a second color, and the third sub-pixel SPX3 may emit light of a third color. For example, the first color may be red, the second color may be blue, and the third color may be green. However, the disclosure is not limited thereto.

Each of the sub-pixels SPX1, SPX2, and SPX3 in the display device 10 may include the emission area EMA and the non-emission area. The emission area EMA may be an area in which the light emitting elements ED are disposed to emit light of a wavelength band. The non-emission area may be a region in which the light emitting element ED is not disposed and a region from which light is not emitted because light emitted from the light emitting element ED does not reach there.

The bank layer BNL may surround the emission area EMA in a plan view, thereby separating and defining the emission areas EMA of the respective sub-pixels SPX1, SPX2, and SPX3. For example, the bank layer BNL may define a first emission area EMA1, a second emission area EMA2, and a third emission area EMA3. The first emission area EMA1 and the second emission area EMA2 may be disposed adjacent to each other in the first direction DR1. The first emission area EMA1 and the second emission area EMA2 may be alternately disposed in the first direction DR1. The third emission area EMA3 may be disposed to be spaced apart from the first emission area EMA1 and the second emission area EMA2 in the second direction DR2. The third emission area EMA3 may be repeatedly arranged in the first direction DR1.

The first electrodes FRM and the second electrodes SRM may have a shape extending in a direction and may be disposed for the respective sub-pixels SPXn. The first electrodes FRM and the second electrodes SRM may be disposed in the emission areas EMA of the respective sub-pixels SPXn while extending in the first direction DR1, and may be disposed to be spaced from each other in the second direction DR2.

Each sub-pixel SPXn may include the first electrode FRM and the second electrode SRM disposed in each emission area EMA. The first electrode FRM may be disposed on the left side with respect to the center of the emission area EMA, and the second electrode SRM may be spaced apart from the first electrode FRM in the second direction DR2 and disposed on the right side with respect to the center of the emission area EMA. The first electrode FRM and the second electrode SRM disposed in the emission areas EMA of the different sub-pixels SPXn may be spaced apart from each other between the emission areas EMA.

The first sub-pixel SPX1 may include the first emission area EMA1, and a first electrode FRM1 and a second electrode SRM1 disposed in the first emission area EMA1. The second sub-pixel SPX2 may include the second emission area EMA2, and a first electrode FRM2 and a second electrode SRM2 disposed in the second emission area EMA2. The third sub-pixel SPX3 may include the third emission area EMA3, and a first electrode FRM3 and a second electrode SRM3 disposed in the third emission area EMA3.

The first electrode FRM1 and the second electrode SRM1 of the first emission area EMA1 may extend in the first direction DR1. The first electrode FRM2 and the second electrode SRM2 of the second emission area EMA2 may extend in the first direction DR1. The first electrode FRM3 and the second electrode SRM3 of the third emission area EMA3 may extend in the first direction DR1. In one embodiment, the extension direction of the first electrode FRM1 of the first emission area EMA1 may be aligned with the extension direction of the first electrode FRM2 of the second emission area EMA2. The extension direction of the second electrode SRM1 of the first emission area EMA1 may be aligned with the extension direction of the second electrode SRM2 of the second emission area EMA2. The first electrode FRM3 of the third emission area EMA3 may be spaced apart from the first electrode FRM1 of the first emission area EMA1 in the second direction DR2. The second electrode SRM3 of the third emission area EMA3 may be spaced apart from the second electrode SRM1 of the first emission area EMA1 in the second direction DR2.

The first emission area EMA1 and the second emission area EMA2, which are adjacent to each other in the first direction DR1, may emit light of different colors. For example, the first emission area EMA1 may emit red light, and the second emission area EMA2 may emit blue light. In one embodiment, the light emitting elements ED disposed in the first emission area EMA1 and the second emission area EMA2 may be aligned by the alignment signal of the first electrode FRM and the second electrode SRM. As described above, the first electrode FRM and the second electrode SRM may be separated after the alignment process of the light emitting elements ED. Therefore, in the alignment process of the light emitting elements ED, the light emitting elements ED of the first emission area EMA1 and the light emitting elements ED of the second emission area EMA2 may be aligned by a same alignment signal. In case that the emission areas EMA emitting light of a same color are disposed in the first direction DR1, a total of three pairs of first electrodes FRM and second electrodes SRM spaced apart in the second direction DR2 may be required. However, according to an embodiment, since the first emission area EMA1 and the second emission area EMA2, which are adjacent to each other in the first direction DR1, emit light of different colors, it may be possible to omit a pair of first electrodes FRM and the second electrode SRM. Accordingly, the number of the first electrodes FRM and the second electrodes SRM may be reduced to form more emission areas EMA, thereby implementing a high-resolution display device 10.

The sizes of the emission areas EMA may be the same or different in a plan view. For example, the size of the first emission area EMA1 and the size of the second emission area EMA2 may be the same, and the size of the third emission area EMA3 may be greater than the size of the first emission area EMA1 or the size of the second emission area EMA2. However, the disclosure is not limited thereto, and the size of the emission area EMA may be adjusted according to the color of light emitted by each emission area EMA.

According to the size of each emission area EMA, the extended length of the first electrode FRM may be different from the extended length of the second electrode SRM. For example, the length of the first electrode FRM1 of the first emission area EMA1 and the length of the first electrode FRM2 of the second emission area EMA2 may be the same in the first direction DR1. The length of the first electrode FRM3 of the third emission area EMA3 may be greater than the length of the first electrode FRM1 of the first emission area EMA1 in the first direction DR1.

The light emitting elements ED disposed in each emission area EMA may be disposed between the first electrode FRM and the second electrode SRM. Ends of the light emitting elements ED may overlap the first electrode FRM in a plan view, and another ends of the light emitting elements ED may overlap the second electrode SRM in a plan view.

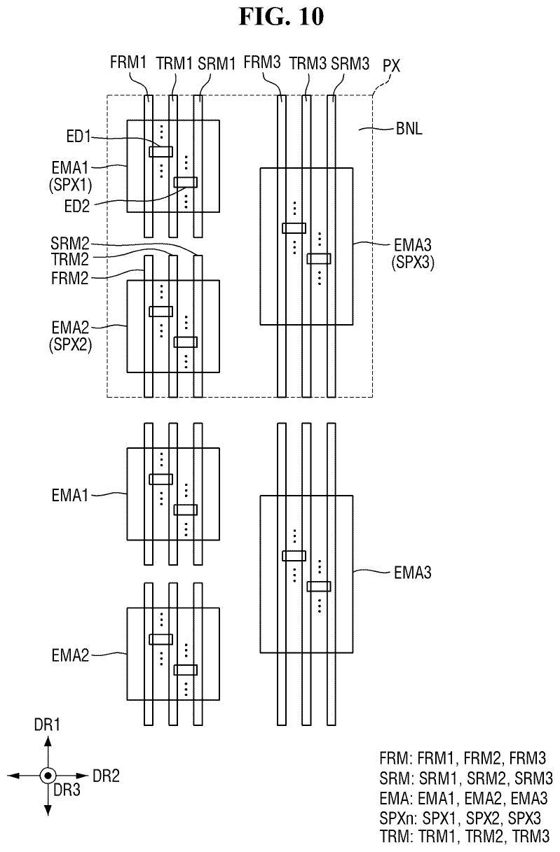

FIG. 10 is a plan view illustrating multiple pixels of a display device according to another embodiment.

Referring to FIG. 10, the embodiment is different from the embodiment of FIG. 9 described above in that each emission area EMA of each sub-pixel SPXn of the display device 10 further includes a third electrode TRM. In the following description, redundant description of the above-described embodiments will be omitted while focusing on differences.

Each sub-pixel SPXn may further include the third electrode TRM. The third electrode TRM may have a shape extending in a direction and may be disposed for each sub-pixel SPXn. The third electrode TRM may be disposed in the emission area EMA of each sub-pixel SPXn while extending in the first direction DR1, and may be disposed between the first electrode FRM and the second electrode SRM.

The first sub-pixel SPX1 may include the first emission area EMA1, and the first electrode FRM1, the second electrode SRM1 and a third electrode TRM1 disposed in the first emission area EMA1. The second sub-pixel SPX2 may include the second emission area EMA2, and the first electrode FRM2, the second electrode SRM2 and a third electrode TRM2 disposed in the second emission area EMA2. The third sub-pixel SPX3 may include the third emission area EMA3, and the first electrode FRM3, the second electrode SRM3, and a third electrode TRM3 disposed in the third emission area EMA3.

The third electrode TRM1 of the first emission area EMA1, the third electrode TRM2 of the second emission area EMA2, and the third electrode TRM3 of the third emission area EMA3 may extend in the first direction DR1, respectively. In one embodiment, the extension direction of the third electrode TRM1 of the first emission area EMA1 may be aligned with the extension direction of the third electrode TRM2 of the second emission area EMA2. The third electrode TRM3 of the third emission area EMA3 may be spaced apart from the third electrode TRM1 of the first emission area EMA1 in the second direction DR2.

The light emitting elements ED disposed in each emission area EMA may include a first light emitting element ED1 and a second light emitting element ED2. The first light emitting element ED1 may be disposed between the first electrode FRM and the third electrode TRM, and the second light emitting element ED2 may be disposed between the second electrode SRM and the third electrode TRM. Ends of the first light emitting elements ED1 may overlap the first electrode FRM in a plan view, and another ends of the first light emitting elements ED1 may overlap the third electrode TRM in a plan view. Ends of the second light emitting elements ED2 may overlap the third electrode TRM in a plan view, and another ends of the second light emitting elements ED2 may overlap the second electrode SRM in a plan view.

In one embodiment, the third electrodes TRM of the respective sub-pixels SPXn may extend in the first direction DR1, and the first emission area EMA1 and the second emission area EMA2, which are adjacent to each other in the first direction DR1, may emit light of different colors. Accordingly, the number of each of the electrodes FRM, SRM, and TRM may be reduced to form more emission areas EMA, thereby implementing the high-resolution display device 10.

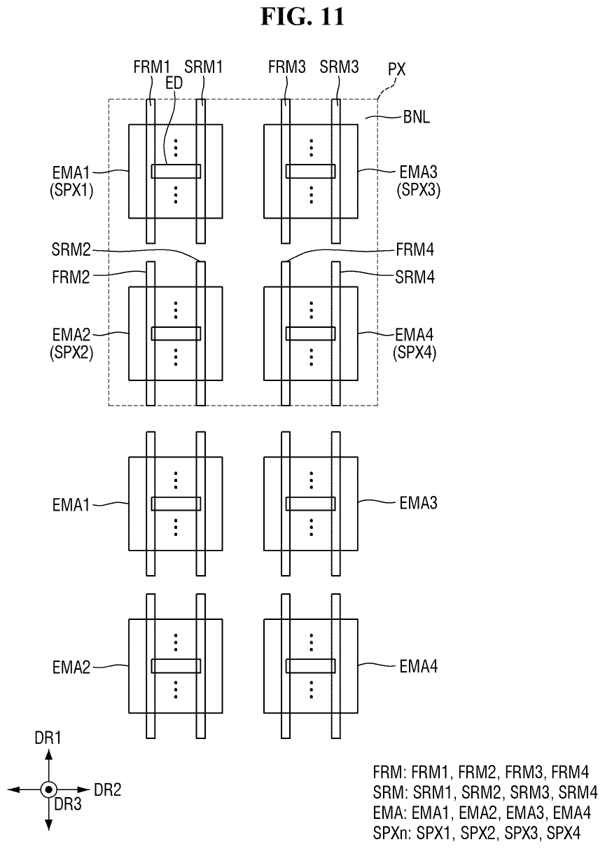

FIG. 11 is a plan view illustrating multiple pixels of a display device according to still another embodiment.

Referring to FIG. 11, the embodiment is different from the embodiment of FIG. 9 in that the pixel PX of the display device 10 further includes a fourth sub-pixel SPX4.

The pixel PX of the display device 10 may further include the fourth sub-pixel SPX4. For example, a pixel PX may include the first sub-pixel SPX1, the second sub-pixel SPX2, the third sub-pixel SPX3, and the fourth sub-pixel SPX4. The fourth sub-pixel SPX4 may be disposed to be spaced apart from the second sub-pixel SPX2 in the second direction DR2 and to be spaced apart from the third sub-pixel SPX3 in the first direction DR1. The first sub-pixel SPX1 may emit light of the first color, the second sub-pixel SPX2 may emit light of the second color, and the third sub-pixel SPX3 and the fourth sub-pixel SPX4 may emit light of the third color. For example, the first color may be red, the second color may be blue, and the third color may be green. However, the disclosure is not limited thereto.

The fourth sub-pixel SPX4 may include a fourth emission area EMA4, a first electrode FRM4, a second electrode SRM4, and the light emitting elements ED. The fourth emission area EMA4 may be disposed to be spaced apart from the third emission area EMA3 in the first direction DR1 and to be spaced apart from the second emission area EMA2 in the second direction DR2.

The first electrode FRM4 and the second electrode SRM4 of the fourth emission area EMA4 may extend in the first direction DR1 and may be disposed to be spaced apart from each other in the second direction DR2. In one embodiment, the extension direction of the first electrode FRM3 of the third emission area EMA3 may be aligned with the extension direction of the first electrode FRM4 of the fourth emission area EMA4. The extension direction of the second electrode SRM3 of the third emission area EMA3 may be aligned with the extension direction of the second electrode SRM4 of the fourth emission area EMA4. The first electrode FRM4 of the fourth emission area EMA4 may be spaced apart from the first electrode FRM2 of the second emission area EMA2 in the second direction DR2. The second electrode SRM4 of the fourth emission area EMA4 may be spaced apart from the second electrode SRM2 of the second emission area EMA2 in the second direction DR2.

The third emission area EMA3 and the fourth emission area EMA4, which are adjacent to each other in the first direction DR1, may emit light of a same color. For example, the third emission area EMA3 and the fourth emission area EMA4 may emit green light. In one embodiment, the light emitting elements ED disposed in the third emission area EMA3 and the fourth emission area EMA4 may be aligned by a same alignment signal of the first electrode FRM and the second electrode SRM.

The sizes of the emission areas EMA may be the same in a plan view. For example, the size of the first emission area EMA1, size of the second emission area EMA2, the size of the third emission area EMA3, and the size of the fourth emission area EMA4 may be the same. However, the disclosure is not limited thereto, and the sizes of the emission areas EMA may be adjusted according to the color of light emitted by each emission area EMA.

According to the size of each emission area EMA, the extended length of the first electrode FRM and the extended length of the second electrode SRM may be the same. For example, the length of the first electrode FRM1 of the first emission area EMA1, the length of the first electrode FRM2 of the second emission area EMA2, the length of the first electrode FRM3 of the third emission area EMA3, and the length of the first electrode FRM4 of the fourth emission area EMA4 may be the same in the first direction DR1.

In an embodiment, the first emission area EMA1 and the second emission area EMA2, which are adjacent to each other in the first direction DR1, may emit light of different colors, and the third emission area EMA3 and the fourth emission area EMA4, which are adjacent to each other in the first direction DR1, may emit light of a same color. Accordingly, the number of each of the electrodes FRM and SRM may be reduced to form more emission areas EMA, thereby implementing the high-resolution display device 10.

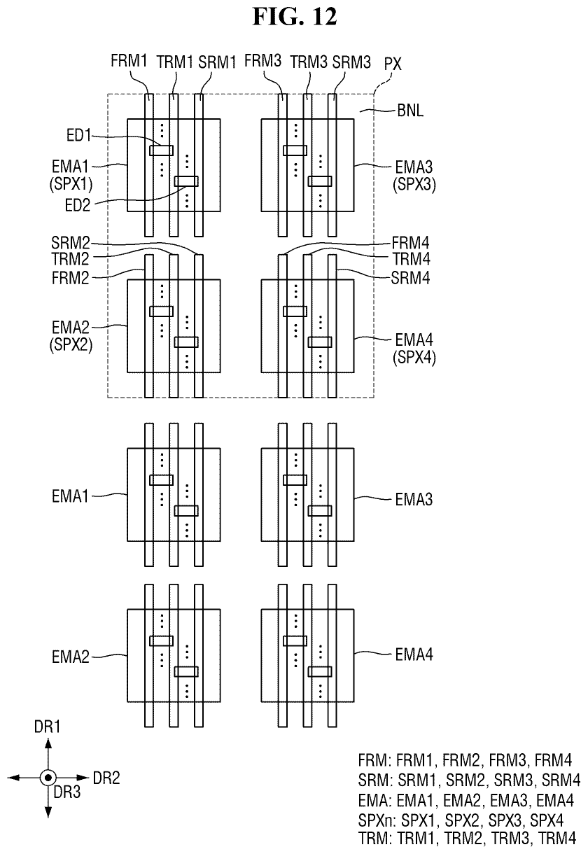

FIG. 12 is a plan view illustrating multiple pixels of a display device according to still another embodiment.

Referring to FIG. 12, the embodiment is different from the embodiment of FIG. 11 described above in that each emission area EMA of each sub-pixel SPXn of the display device 10 further includes the third electrode TRM.

Each sub-pixel SPXn may further include the third electrode TRM. The third electrode TRM may have a shape extending in a direction and may be disposed for each sub-pixel SPXn. The third electrode TRM may be disposed in the emission area EMA of each sub-pixel SPXn while extending in the first direction DR1, and may be disposed between the first electrode FRM and the second electrode SRM.

The first sub-pixel SPX1 may include the first emission area EMA1, and the first electrode FRM1, the second electrode SRM1 and the third electrode TRM1 disposed in the first emission area EMA1. The second sub-pixel SPX2 may include the second emission area EMA2, and the first electrode FRM2, the second electrode SRM2 and the third electrode TRM2 disposed in the second emission area EMA2. The third sub-pixel SPX3 may include the third emission area EMA3, and the first electrode FRM3, the second electrode SRM3, and the third electrode TRM3 disposed in the third emission area EMA3. The fourth sub-pixel SPX4 may include the fourth emission area EMA4, and the first electrode FRM4, the second electrode SRM4, and a third electrode TRM4 disposed in the fourth emission area EMA4.

The third electrode TRM1 of the first emission area EMA1, the third electrode TRM2 of the second emission area EMA2, the third electrode TRM3 of the third emission area EMA3 and the third electrode TRM4 of the fourth emission area EMA4 may extend in the first direction DR1, respectively. In one embodiment, the extension direction of the third electrode TRM3 of the third emission area EMA3 may be aligned with the extension direction of the third electrode TRM4 of the fourth emission area EMA4. The third electrode TRM3 of the third emission area EMA3 may be spaced apart from the third electrode TRM1 of the first emission area EMA1 in the second direction DR2. The third electrode TRM4 of the fourth emission area EMA4 may be spaced apart from the third electrode TRM2 of the second emission area EMA2 in the second direction DR2.

The light emitting elements ED disposed in each emission area EMA may include the first light emitting element ED1 and the second light emitting element ED2. The first light emitting element ED1 may be disposed between the first electrode FRM and the third electrode TRM, and the second light emitting element ED2 may be disposed between the second electrode SRM and the third electrode TRM. Ends of the first light emitting elements ED1 may overlap the first electrode FRM in a plan view, and another ends of the first light emitting elements ED1 may overlap the third electrode TRM in a plan view. Ends of the second light emitting elements ED2 may overlap the third electrode TRM in a plan view, and another ends of the second light emitting elements ED2 may overlap the second electrode SRM in a plan view.

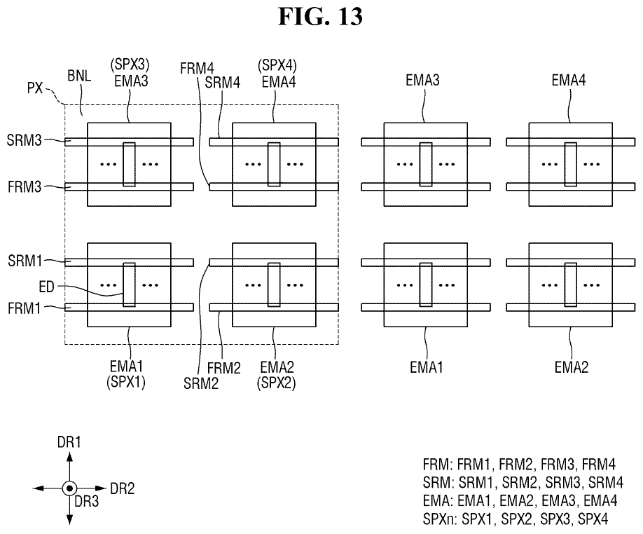

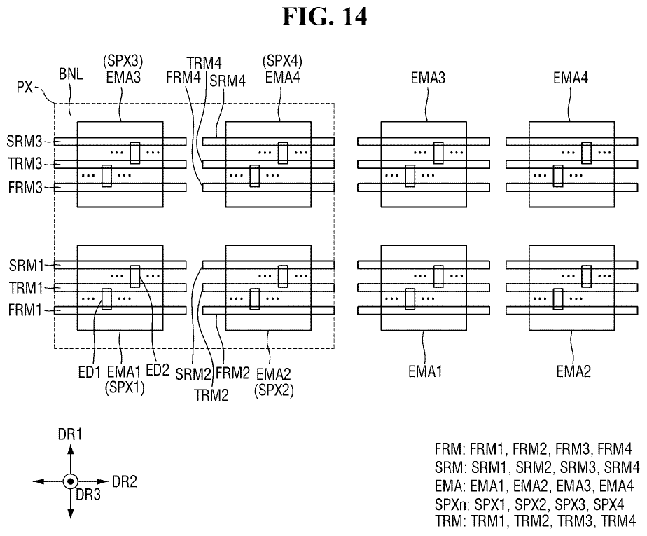

FIGS. 13 and 14 are plan views illustrating multiple pixels of a display device according to still another embodiment.

Referring to FIGS. 13 and 14, the embodiment is different from the embodiment of FIGS. 11 and 12 described above in that the first electrode FRM and the second electrode SRM of each sub-pixel SPXn extend in the second direction DR2 while being spaced apart from each other in the first direction DR1.

Referring to FIGS. 13 and 14, the first emission area EMA1 and the second emission area EMA2 may be disposed adjacent to each other in the second direction DR2. The third emission area EMA3 and the fourth emission area EMA4 may be disposed adjacent to each other in the second direction DR2. The first emission area EMA1 and the second emission area EMA2 may be disposed alternately in the second direction DR2. The third emission area EMA3 and the fourth emission area EMA4 may be disposed alternately in the second direction DR2. The third emission area EMA3 may be disposed to be spaced apart from the first emission area EMA1 in the first direction DR1. The fourth emission area EMA4 may be disposed to be spaced apart from the second emission area EMA2 in the first direction DR1.

The first electrodes FRM and the second electrodes SRM may have a shape extending in a direction and may be disposed for the respective sub-pixels SPXn.

As shown in FIG. 13, the first electrode FRM and the second electrode SRM may be disposed in the emission area EMA of each sub-pixel SPXn while extending in the second direction DR2, and may be disposed to be spaced apart from each other in the first direction DR1. The first electrode FRM may be located on the lower side with respect to the center of the emission area EMA, and the second electrode SRM may be located on the upper side with respect to the center of each emission area EMA while being spaced apart from the first electrode FRM in the first direction DR1.

For example, the first electrode FRM1 and the second electrode SRM1 of the first emission area EMA1 may extend in the second direction DR2. The first electrode FRM2 and the second electrode SRM2 of the second emission area EMA2 may extend in the second direction DR2. The first electrode FRM3 and the second electrode SRM3 of the third emission area EMA3 may extend in the second direction DR2. The first electrode FRM4 and the second electrode SRM4 of the fourth emission area EMA4 may extend in the second direction DR2. In one embodiment, the extension direction of the first electrode FRM1 of the first emission area EMA1 may be aligned with the extension direction of the first electrode FRM2 of the second emission area EMA2. The extension direction of the second electrode SRM1 of the first emission area EMA1 may be aligned with the extension direction of the second electrode SRM2 of the second emission area EMA2. The extension direction of the first electrode FRM3 of the third emission area EMA3 may be aligned with the extension direction of the first electrode FRM4 of the fourth emission area EMA4. The extension direction of the second electrode SRM3 of the third emission area EMA3 may be aligned with the extension direction of the second electrode SRM4 of the fourth emission area EMA4. The first electrode FRM3 of the third emission area EMA3 may be spaced apart from the first electrode FRM1 of the first emission area EMA1 in the first direction DR1. The second electrode SRM3 of the third emission area EMA3 may be spaced apart from the second electrode SRM1 of the first emission area EMA1 in the first direction DR1.

The first emission area EMA1 and the second emission area EMA2, which are adjacent to each other in the second direction DR2, may emit light of different colors. For example, the first emission area EMA1 may emit red light, and the second emission area EMA2 may emit blue light. The third emission area EMA3 and the fourth emission area EMA4, which are adjacent to each other in the second direction DR2, may emit light of a same color. For example, the third emission area EMA3 and the fourth emission area EMA4 may emit green light.

In an embodiment, as shown in FIG. 14, the third electrode TRM may be disposed in the emission area EMA of each sub-pixel SPXn while extending in the second direction DR2, and the first electrode FRM, the second electrode SRM, and the third electrode TRM may be spaced apart from each other in the first direction DR1. The third electrode TRM may be disposed between the first electrode FRM and the second electrode SRM.

For example, the third electrode TRM1 of the first emission area EMA1 may extend in the second direction DR2. The third electrode TRM2 of the second emission area EMA2 may extend in the second direction DR2. The third electrode TRM3 and the second electrode SRM3 of the third emission area EMA3 may extend in the second direction DR2. The third electrode TRM4 of the fourth emission area EMA4 may extend in the second direction DR2. In one embodiment, the extension direction of the third electrode TRM1 of the first emission area EMA1 may be aligned with the extension direction of the third electrode TRM2 of the second emission area EMA2. The extension direction of the first electrode FRM3 of the third emission area EMA3 may be aligned with the extension direction of the first electrode FRM4 of the fourth emission area EMA4.

In one embodiment, the electrodes FRM, SRM, and TRM of each sub-pixel SPXn may extend in the second direction DR2, the first emission area EMA1 and the second emission area EMA2, which are adjacent to each other in the second direction DR2, may emit light of different colors, and the third emission area EMA3 and the fourth emission area EMA4 may emit light of a same color. Accordingly, the number of each of the electrodes FRM, SRM, and TRM may be reduced to form more emission areas EMA, thereby implementing the high-resolution display device 10.

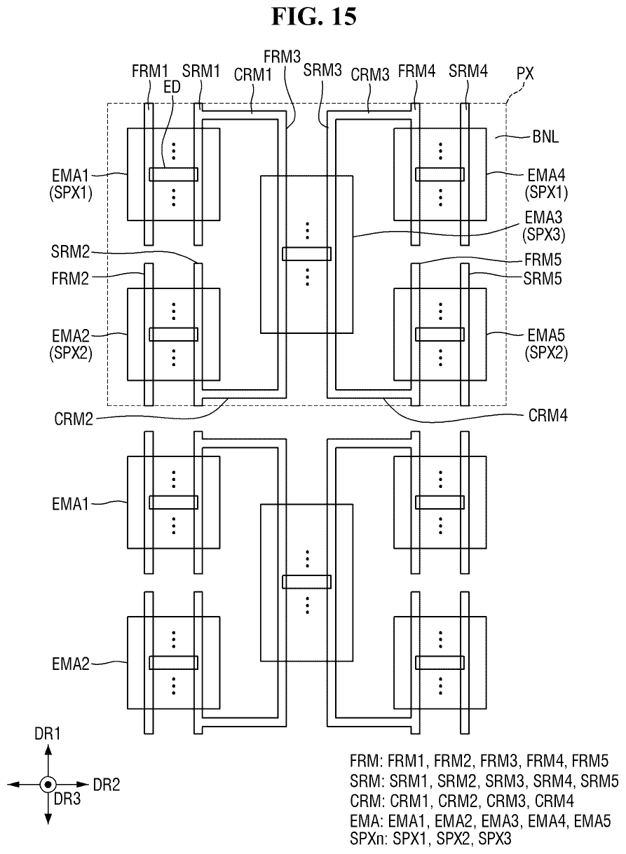

FIG. 15 is a plan view illustrating multiple pixels of a display device according to still another embodiment.

Referring to FIG. 15, the embodiment is different from the embodiment of FIG. 9 described above in that the second electrode SRM1 of the first emission area EMA1 may be connected to the first electrode FRM3 of the third emission area EMA3, and the second electrode SRM2 of the second emission area EMA2 may be connected to the first electrode FRM3 of the third emission area EMA3.

The pixel PX of the display device 10 may include the first sub-pixel SPX1, the second sub-pixel SPX2, and the third sub-pixel SPX3. The pixels PX may be repeatedly disposed in the first direction DR1 and the second direction DR2. For example, the first sub-pixel SPX1 and the second sub-pixel SPX2 of a pixel PX may be repeatedly disposed in the first direction DR1, and the third sub-pixel SPX3 of a pixel PX may be disposed to be spaced apart from the first sub-pixel SPX1 in the second direction DR2. In the second direction DR2 of the third sub-pixel SPX3, the first sub-pixel SPX1, the second sub-pixel SPX2, and the third sub-pixel SPX3 of another pixel PX may be disposed.

In the following description, the emission areas EMA of the first sub-pixel SPX1 and the second sub-pixel SPX2 of another adjacent pixel PX will be referred to as the fourth emission area EMA4 and a fifth emission area EMA5, respectively.

The first electrode FRM and the second electrode SRM, which extend in the first direction DR1 and are spaced apart from each other in the second direction DR2, may be disposed in each emission area EMA. For example, the fourth emission area EMA4 may include the first electrode FRM4 and the second electrode SRM4, and the fifth emission area EMA5 may include a first electrode FRM5 and a second electrode SRM5.

In one embodiment, the second electrode SRM1 of the first emission area EMA1 and the second electrode SRM2 of the second emission area EMA2 may be connected to the first electrode FRM3 of the third emission area EMA3. The first electrode FRM4 of the fourth emission area EMA4 and the first electrode FRM5 of the fifth emission area EMA5 may be connected to the second electrode SRM3 of the third emission area EMA3.

A first connection electrode CRM1 may be disposed between the second electrode SRM1 of the first emission area EMA1 and the first electrode FRM3 of the third emission area EMA3 to connect the second electrode SRM1 of the first emission area EMA1 to the first electrode FRM3 of the third emission area EMA3. A second connection electrode CRM2 may be disposed between the second electrode SRM2 of the second emission area EMA2 and the first electrode FRM3 of the third emission area EMA3 to connect the second electrode SRM2 of the second emission area EMA2 to the first electrode FRM3 of the third emission area EMA3. A third connection electrode CRM3 may be disposed between the second electrode SRM3 of the third emission area EMA3 and the first electrode FRM4 of the fourth emission area EMA4 to connect the second electrode SRM3 of the third emission area EMA3 to the first electrode FRM4 of the fourth emission area EMA4. A fourth connection electrode CRM4 may be disposed between the second electrode SRM3 of the third emission area EMA3 and the first electrode FRM5 of the fifth emission area EMA5 to connect the second electrode SRM3 of the third emission area EMA3 to the first electrode FRM5 of the fifth emission area EMA5.

The first to fourth connection electrodes CRM1, CRM2, CRM3, and CRM4 may extend in the second direction DR2 and may be disposed to be spaced apart from each other in the first direction DR1. The second electrode SRM1 of the first emission area EMA1, the first connection electrode CRM1, the second connection electrode CRM2, the second electrode SRM2 of the second emission area EMA2, and the first electrode FRM3 of the third emission area EMA3 may be integral with each other. The first electrode FRM4 of the fourth emission area EMA4, the third connection electrode CRM3, the fourth connection electrode CRM4, the first electrode FRM5 of the fifth emission area EMA5, and the second electrode SRM3 of the third emission area EMA3 may be integral with each other.

In an embodiment, the second electrode SRM1 of the first emission area EMA1, the second electrode SRM2 of the second emission area EMA2, and the first electrode FRM3 of the third emission area EMA3 may be connected, and the first electrode FRM4 of the fourth emission area EMA4, the first electrode FRM5 of the fifth emission area EMA5, and the second electrode SRM3 of the third emission area EMA3 may be connected, so that the alignment signals of the adjacent emission areas EMA may be shared to facilitate alignment of the light emitting elements ED.

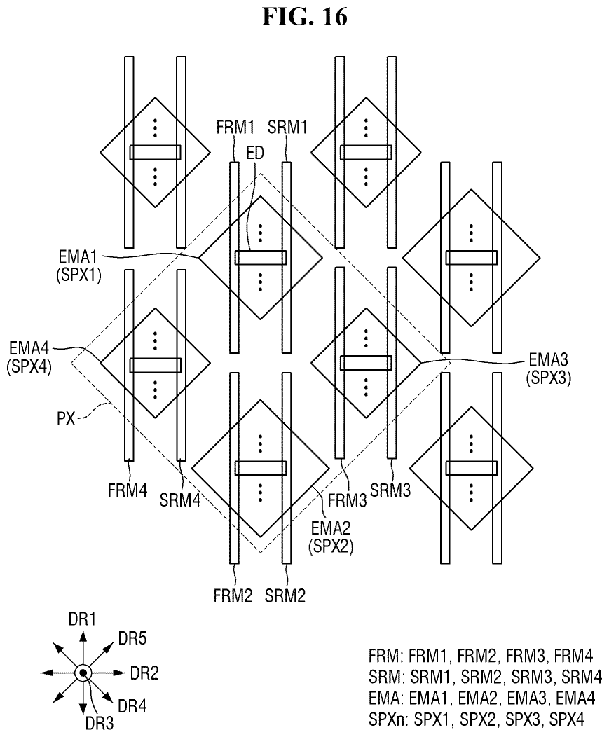

FIG. 16 is a plan view illustrating multiple pixels of a display device according to still another embodiment.

Referring to FIG. 16, the embodiment is different from the embodiment of FIGS. 9 to 15 described above in that each pixel PX may include the first sub-pixel SPX1, the second sub-pixel SPX2, the third sub-pixel SPX3, and the fourth sub-pixel SPX4 formed in PenTile™ or Diamond Pixel™.

The pixel PX of the display device 10 may include the first sub-pixel SPX1, the second sub-pixel SPX2, the third sub-pixel SPX3, and the fourth sub-pixel SPX4. The first sub-pixel SPX1 and the second sub-pixel SPX2 may be disposed adjacent to each other in the first direction DR1. The third sub-pixel SPX3 may be disposed adjacent to the first sub-pixel SPX1 in a fourth direction DR4, and the fourth sub-pixel SPX4 may be disposed adjacent to the first sub-pixel SPX1 in a fifth direction DR5. The first sub-pixel SPX1 and the second sub-pixel SPX2 may be disposed alternately in the first direction DR1. The third sub-pixel SPX3 and the fourth sub-pixel SPX4 may be disposed repeatedly in the first direction DR1, respectively.

The first sub-pixel SPX1 may emit light of the first color, the second sub-pixel SPX2 may emit light of the second color, and the third sub-pixel SPX3 and the fourth sub-pixel SPX4 may emit light of the third color. For example, the first color may be red, the second color may be blue, and the third color may be green. However, the disclosure is not limited thereto.

Each sub-pixel SPXn may include the emission area EMA. For example, the first sub-pixel SPX1 may include the first emission area EMA1, the second sub-pixel SPX2 may include the second emission area EMA2, the third sub-pixel SPX3 may include the third emission area EMA3, and the fourth sub-pixel SPX4 may include the fourth emission area EMA4. Each emission area EMA may have a quadrangular shape in a plan view where two sides extending in the fourth direction DR4 meet two sides extending in the fifth direction DR5.

Each emission area EMA may include the first electrode FRM and the second electrode SRM that extend in the first direction DR1 and are spaced apart from each other in the second direction DR2. In one embodiment, the extension direction of the first electrode FRM1 of the first emission area EMA1 may be aligned with the extension direction of the first electrode FRM2 of the second emission area EMA2. The extension direction of the second electrode SRM1 of the first emission area EMA1 may be aligned with the extension direction of the second electrode SRM2 of the second emission area EMA2.

The first emission area EMA1 and the second emission area EMA2, which are adjacent to each other in the first direction DR1, may emit light of different colors. Further, the third emission area EMA3 and the fourth emission area EMA4, which are adjacent to each other in the second direction DR2, may emit light of a same color.

The sizes of the emission areas EMA may be the same or different in a plan view. For example, the size of the second emission area EMA2 may be greater than the size of the first emission area EMA1, and the size of the first emission area EMA1 may be greater than the size of the third emission area EMA3 or the size of the fourth emission area EMA4. The size of the third emission area EMA3 and the size of the fourth emission area EMA4 may be the same. However, the disclosure is not limited thereto, and the sizes of the emission areas EMA may be adjusted according to the color of light emitted by each emission area EMA.

In an embodiment, the first emission area EMA1 and the second emission area EMA2, which are adjacent to each other in the first direction DR1, may emit light of different colors, and the third emission area EMA3 and the fourth emission area EMA4, which are adjacent to each other in the second direction DR2, may emit light of a same color. Accordingly, the number of each of the electrodes FRM and SRM may be reduced to form more emission areas EMA, thereby implementing the high-resolution display device 10.

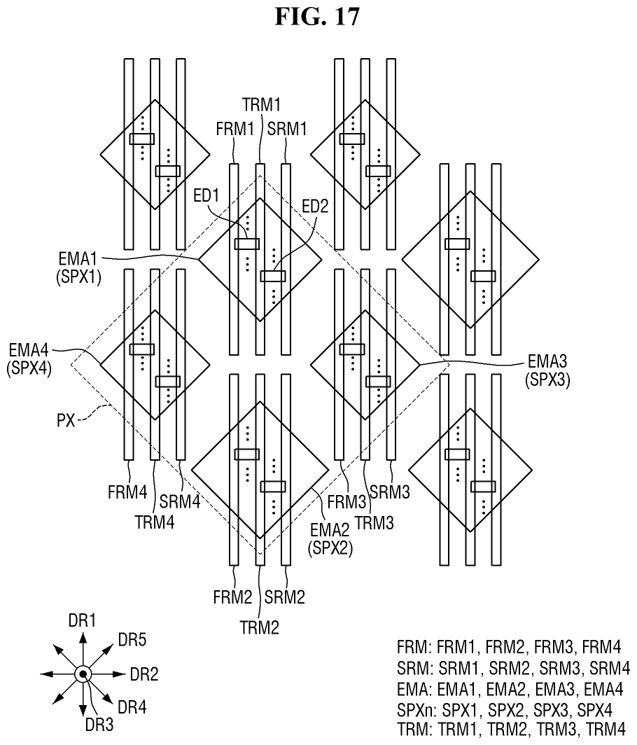

FIG. 17 is a plan view illustrating multiple pixels of a display device according to still another embodiment.

Referring to FIG. 17, the embodiment is different from the embodiment of FIG. 16 described above in that each emission area EMA of each sub-pixel SPXn of the display device 10 may further include the third electrode TRM.

Each sub-pixel SPXn may further include the third electrode TRM. The third electrode TRM may have a shape extending in a direction and may be disposed for each sub-pixel SPXn. The third electrode TRM may be disposed in the emission area EMA of each sub-pixel SPXn while extending in the first direction DR1, and may be disposed between the first electrode FRM and the second electrode SRM.

The first sub-pixel SPX1 may include the first emission area EMA1, and the first electrode FRM1, the second electrode SRM1 and a third electrode TRM1 disposed in the first emission area EMA1. The second sub-pixel SPX2 may include the second emission area EMA2, and the first electrode FRM2, the second electrode SRM2 and a third electrode TRM2 disposed in the second emission area EMA2. The third sub-pixel SPX3 may include the third emission area EMA3, and the first electrode FRM3, the second electrode SRM3, and a third electrode TRM3 disposed in the third emission area EMA3. The fourth sub-pixel SPX4 may include the fourth emission area EMA4, and the first electrode FRM4, the second electrode SRM4, and the third electrode TRM4 disposed in the fourth emission area EMA4.

The third electrode TRM1 of the first emission area EMA1, the third electrode TRM2 of the second emission area EMA2, the third electrode TRM3 of the third emission area EMA3 and the third electrode TRM4 of the fourth emission area EMA4 may extend in the first direction DR1, respectively. In one embodiment, the extension direction of the third electrode TRM3 of the third emission area EMA3 may be parallel to the extension direction of the third electrode TRM4 of the fourth emission area EMA4. The third electrode TRM3 of the third emission area EMA3 may be spaced apart from the third electrode TRM1 of the first emission area EMA1 in the second direction DR2. The third electrode TRM4 of the fourth emission area EMA4 may be spaced apart from the third electrode TRM2 of the second emission area EMA2 in the second direction DR2.

The light emitting elements ED disposed in each emission area EMA may include the first light emitting element ED1 and the second light emitting element ED2. The first light emitting element ED1 may be disposed between the first electrode FRM and the third electrode TRM, and the second light emitting element ED2 may be disposed between the second electrode SRM and the third electrode TRM. Ends of the first light emitting elements ED1 may overlap the first electrode FRM in a plan view, and another ends of the first light emitting elements ED1 may overlap the third electrode TRM in a plan view. Ends of the second light emitting elements ED2 may overlap the third electrode TRM in a plan view, and another ends of the second light emitting elements ED2 may overlap the second electrode SRM in a plan view.

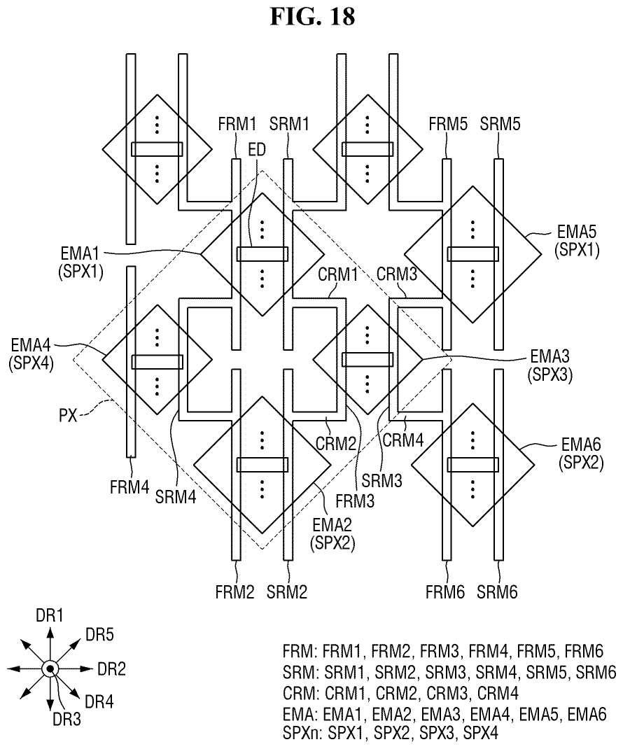

FIG. 18 is a plan view illustrating multiple pixels of a display device according to still another embodiment.

Referring to FIG. 18, the embodiment is different from the embodiment of FIG. 16 described above in that the second electrode SRM1 of the first emission area EMA1 may be connected to the first electrode FRM3 of the third emission area EMA3, and the second electrode SRM2 of the second emission area EMA2 may be connected to the first electrode FRM3 of the third emission area EMA3.

The pixel PX of the display device 10 may include the first sub-pixel SPX1, the second sub-pixel SPX2, the third sub-pixel SPX3, and the fourth sub-pixel SPX4. The pixels PX may be repeatedly disposed in the first direction DR1 and the second direction DR2. For example, the first sub-pixel SPX1 and the second sub-pixel SPX2 of a pixel PX may be repeatedly disposed in the first direction DR1. The third sub-pixel SPX3 may be disposed to be spaced apart from the first sub-pixel SPX1 in the second direction DR2. The fourth sub-pixel SPX4 may be disposed to be spaced apart from the third sub-pixel SPX3 in the second direction DR2. In the second direction DR2 of the third sub-pixel SPX3, the first sub-pixel SPX1, the second sub-pixel SPX2, the third sub-pixel SPX3, and the fourth sub-pixel SPX4 of another pixel PX may be disposed. The fourth sub-pixel SPX4 of another pixel PX may be the third sub-pixel SPX3 of the adjacent pixel PX.

In the following description, the emission areas EMA of the first sub-pixel SPX1 and the second sub-pixel SPX2 of another adjacent pixel PX may be referred to as the fifth emission area EMA5 and a sixth emission area EMA6, respectively.

The first electrode FRM and the second electrode SRM, which extend in the first direction DR1 and are spaced apart from each other in the second direction DR2, may be disposed in each emission area EMA. For example, the fifth emission area EMA5 may include the first electrode FRM5 and the second electrode SRM5, and the sixth emission area EMA6 may include a first electrode FRM6 and a second electrode SRM6.

In one embodiment, the second electrode SRM1 of the first emission area EMA1 and the second electrode SRM2 of the second emission area EMA2 may be connected to the first electrode FRM3 of the third emission area EMA3. The first electrode FRM5 of the fifth emission area EMA5 and the first electrode FRM6 of the sixth emission area EMA6 may be connected to the second electrode SRM3 of the third emission area EMA3.

The first connection electrode CRM1 may be disposed between the second electrode SRM1 of the first emission area EMA1 and the first electrode FRM3 of the third emission area EMA3 to connect the second electrode SRM1 of the first emission area EMA1 to the first electrode FRM3 of the third emission area EMA3. The second connection electrode CRM2 may be disposed between the second electrode SRM2 of the second emission area EMA2 and the first electrode FRM3 of the third emission area EMA3 to connect the second electrode SRM2 of the second emission area EMA2 to the first electrode FRM3 of the third emission area EMA3. The third connection electrode CRM3 may be disposed between the second electrode SRM3 of the third emission area EMA3 and the first electrode FRM5 of the fifth emission area EMA5 to connect the second electrode SRM3 of the third emission area EMA3 to the first electrode FRM5 of the fifth emission area EMA5. The fourth connection electrode CRM4 may be disposed between the second electrode SRM3 of the third emission area EMA3 and the first electrode FRM6 of the sixth emission area EMA6 to connect the second electrode SRM3 of the third emission electrode EMA3 to the first electrode FRM6 of the sixth emission area EMA6.

The first to fourth connection electrodes CRM1, CRM2, CRM3, and CRM4 may extend in the second direction DR2 and may be disposed to be spaced apart from each other in the first direction DR1. The second electrode SRM1 of the first emission area EMA1, the first connection electrode CRM1, the second connection electrode CRM2, the second electrode SRM2 of the second emission area EMA2, and the first electrode FRM3 of the third emission area EMA3 may be integral with each other. The first electrode FRM5 of the fifth emission area EMA5, the third connection electrode CRM3, the fourth connection electrode CRM4, the first electrode FRM6 of the sixth emission area EMA6, and the second electrode SRM3 of the third emission area EMA3 may be integral with each other.

In an embodiment, the second electrode SRM1 of the first emission area EMA1, the second electrode SRM2 of the second emission area EMA2, and the first electrode FRM3 of the third emission area EMA3 may be connected, and the first electrode FRM5 of the fifth emission area EMA5, the first electrode FRM6 of the sixth emission area EMA6, and the second electrode SRM3 of the third emission area EMA3 may be connected, so that the alignment signals of the adjacent emission areas EMA may be shared to facilitate alignment of the light emitting elements ED.

As described above, in the display device 10 according to one embodiment, the emission areas EMA, which are adjacent to each other in the first direction DR1 or the second direction DR2, may emit light of different colors. Accordingly, the number of each of the electrodes FRM, SRM, and TRM may be reduced to form more emission areas EMA, thereby implementing the high-resolution display device 10.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a substrate; and
a bank layer disposed on the substrate, and defining a first emission area, a second emission area, and a third emission area, wherein
each of the first emission area, the second emission area, and the third emission area comprises:
a first electrode and a second electrode extending in a first direction and spaced apart from each other in a second direction intersecting the first direction; and
a plurality of light emitting elements disposed between the first electrode and the second electrode,
the first emission area and the second emission area are adjacent to each other in the first direction,
the third emission area is spaced apart from the first emission area or the second emission area in the second direction, and
the first emission area, the second emission area, and the third emission area emit light of different colors.

2. The display device of claim 1, wherein
an extension direction of the first electrode of the first emission area is aligned with an extension direction of the first electrode of the second emission area, and
an extension direction of the second electrode of the first emission area is aligned with an extension direction of the second electrode of the second emission area.

3. The display device of claim 1, wherein
the first electrode of the third emission area is spaced apart from the first electrode of the first emission area in the second direction, and
the second electrode of the third emission area is spaced apart from the second electrode of the first emission area in the second direction.

4. The display device of claim 1, wherein
the first emission area emits red light,
the second emission area emits blue light, and
the third emission area emits green light.

5. The display device of claim 1, wherein a size of the third emission area is greater than a size of the first emission area or a size of the second emission area in a plan view.

6. The display device of claim 5, wherein the size of the first emission area is equal to the size of the second emission area.

7. The display device of claim 1, wherein
each of the first emission area, the second emission area, and the third emission area further comprises a third electrode disposed between the first electrode and the second electrode, and
the plurality of light emitting elements comprise first light emitting elements disposed between the first electrode and the third electrode and second light emitting elements disposed between the second electrode and the third electrode.

8. The display device of claim 1, further comprising:
a fourth emission area and a fifth emission area spaced apart in the second direction with the third emission area interposed between the fourth emission area and the fifth emission area,
wherein each of the fourth emission area and the fifth emission area comprises the first electrode, the second electrode, and the plurality of light emitting elements.

9. The display device of claim 8, wherein
the fourth emission area and the first emission area emit light of a same color, and
the fifth emission area and the second emission area emit light of a same color.

10. The display device of claim 8, wherein
each of the second electrode of the first emission area and the second electrode of the second emission area is connected to the first electrode of the third emission area, and
the first electrode of the fourth emission area and the first electrode of the fifth emission area are connected to the second electrode of the third emission area.

11. A display device comprising:
a substrate; and
a bank layer disposed on the substrate, and defining a first emission area, a second emission area, a third emission area, and a fourth emission area, wherein
each of the first emission area, the second emission area, the third emission area, and the fourth emission area comprises:
a first electrode and a second electrode extending in a first direction and spaced apart from each other in a second direction intersecting the first direction; and
a plurality of light emitting elements disposed between the first electrode and the second electrode,
the first emission area and the second emission area are adjacent to each other in the first direction,
the third emission area and the fourth emission area are adjacent to each other in the first direction,
the third emission area and the fourth emission area are spaced apart from the first emission area or the second emission area in the second direction,
the first emission area, the second emission area, and the third emission area emit light of different colors, and
the third emission area and the fourth emission area emit light of a same color.

12. The display device of claim 11, wherein
an extension direction of the first electrode of the first emission area is aligned with an extension direction of the first electrode of the second emission area, and
an extension direction of the first electrode of the third emission area is aligned with an extension direction of the first electrode of the fourth emission area.

13. The display device of claim 11, wherein
the first electrode of the third emission area and the first electrode of the fourth emission area are spaced apart from the first electrode of the first emission area in the second direction, and
the second electrode of the third emission area and the second electrode of the fourth emission area are spaced apart from the second electrode of the first emission area in the second direction.

14. The display device of claim 11, wherein
the first emission area emits red light,
the second emission area emits blue light, and
the third emission area and the fourth emission area emit green light.

15. The display device of claim 11, wherein sizes of the first emission area, the second emission area, the third emission area, and the fourth emission area are equal in a plan view.

16. The display device of claim 15, wherein lengths of the first electrode of the first emission area, the first electrode of the second emission area, the first electrode of the third emission area, and the first electrode of the fourth emission area are equal in the first direction.

17. The display device of claim 11, wherein
each of the first emission area, the second emission area, the third emission area, and the fourth emission area further comprises a third electrode disposed between the first electrode and the second electrode, and
the plurality of light emitting elements comprise first light emitting elements disposed between the first electrode and the third electrode and second light emitting elements disposed between the second electrode and the third electrode.

18. The display device of claim 11, further comprising:
a fifth emission area and a sixth emission area spaced apart in the second direction with the third emission area interposed between the fifth emission area and the sixth emission area,
wherein each of the fifth emission area and the sixth emission area comprises the first electrode, the second electrode, and the plurality of light emitting elements.

19. The display device of claim 18, wherein
the fifth emission area and the second emission area emit light of a same color, and
the sixth emission area and the first emission area emit light of a same color.

20. The display device of claim 18, wherein
each of the second electrode of the first emission area and the second electrode of the second emission area is connected to the first electrode of the third emission area, and
the first electrode of the fifth emission area and the first electrode of the sixth emission area are connected to the second electrode of the third emission area.
